(19) United States
(12) Patent Application Publication
(10) Pub. No.: US 2024/0416961 A1
(43) Pub. Date: Dec. 19, 2024

(54) DATA PROCESSING METHOD AND APPARATUS, DEVICE, AND COMPUTER-READABLE STORAGE MEDIUM

(71) Applicant: TENCENT TECHNOLOGY (SHENZHEN) COMPANY LIMITED, Shenzhen (CN)

(72) Inventor: Haining DU, Shenzhen (CN)

(21) Appl. No.: 18/816,724

(22) Filed: Aug. 27, 2024

Related U.S. Application Data
(63) Continuation of application No. PCT/CN2023/109281, filed on Jul. 26, 2023.

(30) Foreign Application Priority Data
Sep. 6, 2022 (CN) 202211083216.X

(51) Int. Cl. B60W 60/00; G06F 30/15

(52) U.S. Cl. CPC B60W 60/0011; G06F 30/15

(57) ABSTRACT

A data processing method includes: determining, in a driving simulation system, whether a simulated ramp connected to a simulated main road belongs to a sensing region with sensed data; generating a first virtual simulated vehicle in the simulated ramp at a simulation starting moment if the simulated ramp does not belong to the sensing region with the sensed data; controlling, in a simulation reproduction stage, a driving behavior of at least one second virtual simulated vehicle traveling in the simulated ramp, to obtain a traffic status of the simulated ramp; and controlling, in a simulation prediction stage, based on the traffic status of the simulated ramp, a driving behavior of a third virtual simulated vehicle traveling in the simulated ramp, to obtain a predicted traffic status of the simulated ramp, the predicted traffic status being configured to control a traveling state of a physical vehicle traveling on a physical road.

### CROSS-REFERENCES TO RELATED APPLICATIONS

This application is a continuation of PCT Patent Application No. PCT/CN2023/109281, filed on Jul. 26, 2023, which Chinese Patent Application No. 202211083216.X, filed with the China National Intellectual Property Administration on Sep. 6, 2022 and entitled “DATA PROCESSING METHOD AND APPARATUS, DEVICE, AND COMPUTER-READABLE STORAGE MEDIUM”, the entire contents of both of which are incorporated herein by reference.

### FIELD OF THE TECHNOLOGY

The present disclosure relates to the field of Internet technologies, and in particular, to a data processing method and apparatus, a device, and a computer-readable storage medium.

### BACKGROUND OF THE DISCLOSURE

With the development of the society, roads have become increasingly complex. For example, an interchange includes not only main roads, but also indispensable ramps for entering and exiting the main roads. In this case, relevant personnel need to understand not only traffic status of the main roads, but also traffic status of the ramps.

### SUMMARY

Embodiments of the present disclosure provide a data processing method and apparatus, a device, and a computer-readable storage medium, to improve accuracy of reproducing a physical road by a simulated road, thereby improving accuracy of predicting a traffic status of the physical road.

An embodiment of the present disclosure provides a data processing method, performed by a computer device running a driving simulation system, including: determining, in the driving simulation system, whether a simulated ramp connected to a simulated main road belongs to a sensing region with sensed data; generating a first virtual simulated vehicle in the simulated ramp at a simulation starting moment in response to that the simulated ramp does not belong to the sensing region with the sensed data; controlling, in a simulation reproduction stage after the simulation starting moment, a driving behavior of at least one second virtual simulated vehicle traveling in the simulated ramp according to an autonomous driving model corresponding to the simulated ramp, to obtain a traffic status of the simulated ramp, the at least one second virtual simulated vehicle traveling in the simulated ramp including the first virtual simulated vehicle; and controlling, in a simulation prediction stage after the simulation reproduction stage, based on the traffic status of the simulated ramp obtained in the simulation reproduction stage, a driving behavior of a third virtual simulated vehicle traveling in the simulated ramp according to the autonomous driving model corresponding to the simulated ramp, to obtain a predicted traffic status of the simulated ramp, the predicted traffic status being configured to control a traveling state of a physical vehicle traveling on a physical road corresponding to the simulated ramp.

An embodiment of the present disclosure provides a data processing apparatus, including: a determining module, configured to determine, in a driving simulation system, whether a simulated ramp connected to a simulated main road belongs to a sensing region with sensed data; a vehicle generation module, configured to generate a first virtual simulated vehicle in the simulated ramp at a simulation starting moment in response to that the simulated ramp does not belong to the sensing region with the sensed data; a first outputting module, configured to control, in a simulation reproduction stage after the simulation starting moment, a driving behavior of at least one second virtual simulated vehicle traveling in the simulated ramp according to an autonomous driving model corresponding to the simulated ramp, to obtain a traffic status of the simulated ramp, the at least one second virtual simulated vehicle traveling in the simulated ramp including the first virtual simulated vehicle; and a second outputting module, configured to control, in a simulation prediction stage after the simulation reproduction stage, based on the traffic status of the simulated ramp obtained in the simulation reproduction stage, a driving behavior of a third virtual simulated vehicle traveling in the simulated ramp according to the autonomous driving model corresponding to the simulated ramp, to obtain a predicted traffic status of the simulated ramp, the predicted traffic status being configured to control a traveling state of a physical vehicle traveling on a physical road corresponding to the simulated ramp.

An embodiment of the present disclosure further provides a computer device, including: a processor, a memory, and a network interface. The processor is connected to the memory and the network interface. The network interface is configured to provide a data communication function. The memory is configured to store a computer program. The processor is configured to invoke the computer program, to cause the computer device to perform the method in the embodiments of the present disclosure.

An embodiment of the present disclosure further provides a non-transitory computer-readable storage medium, having a computer program stored therein. The computer program is adapted to be loaded and executed by a processor to perform the method in the embodiments of the present disclosure.

### BRIEF DESCRIPTION OF THE DRAWINGS

FIG. 1 is a schematic architectural diagram of a system according to an embodiment of the present disclosure.

FIG. 2a is a schematic diagram of a topology of a main road with a ramp according to an embodiment of the present disclosure.

FIG. 2b is a schematic structural diagram of an on-ramp according to an embodiment of the present disclosure.

FIG. 2c is a schematic structural diagram of an off-ramp according to an embodiment of the present disclosure.

FIG. 2d is a schematic diagram of a scenario of a sensing coverage region and a sensing blank region according to an embodiment of the present disclosure.

FIG. 2e is a diagram of an example of simulation deduction of a simulated main road for “time” according to an embodiment of the present disclosure.

FIG. 3 is a schematic flowchart of a data processing method according to an embodiment of the present disclosure.

FIG. 4 is a schematic diagram of a scenario of generating a first virtual simulated vehicle in a simulated on-ramp according to an embodiment of the present disclosure.

FIG. 5 is a schematic flowchart of a method for generating a virtual simulated vehicle for a simulated on-ramp at a simulation starting moment according to an embodiment of the present disclosure.

FIG. 6 is a diagram of an example of a broken line of an average vehicle flow according to an embodiment of the present disclosure.

FIG. 7 is a schematic diagram of a basic traffic graph according to an embodiment of the present disclosure.

FIG. 8 is a schematic diagram of a scenario of outputting a virtual simulated driving behavior in a simulated on-ramp according to an embodiment of the present disclosure.

FIG. 9a is a schematic flowchart of a method for generating a virtual simulated driving behavior for a simulated on-ramp in a simulation reproduction stage according to an embodiment of the present disclosure.

FIG. 9b is a schematic flowchart of a method for generating a predicted simulated driving behavior for a simulated on-ramp in a simulation prediction stage according to an embodiment of the present disclosure.

FIG. 10 is a schematic flowchart of a data processing method according to an embodiment of the present disclosure.

FIG. 11 is a schematic flowchart of a method for generating a virtual simulated vehicle for a simulated off-ramp at a simulation starting moment according to an embodiment of the present disclosure.

FIG. 12 is a schematic diagram of a scenario of generating a first virtual simulated vehicle in a simulated off-ramp according to an embodiment of the present disclosure.

FIG. 13 is a schematic diagram of a scenario of outputting a virtual simulated driving behavior in a simulated off-ramp according to an embodiment of the present disclosure.

FIG. 14 is a schematic flowchart of a method for generating a predicted simulated driving behavior for a simulated off-ramp in a simulation prediction stage according to an embodiment of the present disclosure.

FIG. 15 is a schematic flowchart of a data processing method according to an embodiment of the present disclosure.

FIG. 16 is a schematic flowchart of a method for generating a virtual simulated driving behavior for a simulated off-ramp in a simulation reproduction stage according to an embodiment of the present disclosure.

FIG. 17 is a schematic structural diagram of a data processing apparatus according to an embodiment of the present disclosure.

FIG. 18 is a schematic structural diagram of a computer device according to an embodiment of the present disclosure.

### DESCRIPTION OF EMBODIMENTS

The following clearly and completely describes the technical solutions in the embodiments of the present disclosure with reference to the accompanying drawings in the embodiments of the present disclosure. Apparently, the described embodiments are merely some rather than all of the embodiments of the present disclosure. All other embodiments obtained by a person of ordinary skill in the art based on the embodiments of the present disclosure without creative efforts shall fall within the protection scope of the present disclosure.

For ease of understanding, simple explanations of some terms are first provided below:

The intelligent vehicle infrastructure cooperative system (IVICS) is a development direction of the intelligent traffic system (ITS). The IVICS is a safe, efficient, and environmentally friendly road traffic system formed by adopting technologies, such as advanced wireless communication and the new-generation Internet, to comprehensively implement dynamic real-time information exchanges between vehicles and between vehicles and roads and perform active vehicle safety control and road cooperative management based on acquisition and integration of dynamic traffic information in all time and space, thereby fully implementing effective cooperation between people, vehicles, and roads, ensuring traffic safety, and improving traffic efficiency. In the embodiments of the present disclosure, the IVICS may be configured to accurately determine reproduction simulation and prediction simulation of a simulated ramp.

Physical road: A physical road, which may also be referred to as a road, in the embodiments of the present disclosure is a road in the physical world.

Simulated road: A simulated road, which may also be referred to as a virtual road, is a mapping of a physical road in a simulation system, for example, a mapping of elements, such as an environment, a vehicle, and an incident, of a physical road.

Reproduced simulated vehicle: A reproduced simulated vehicle is a simulated vehicle reproduced in a simulation system according to information about a real vehicle included in sensed data acquired by a sensing device on a physical road side. That is, the reproduction simulated vehicle is a mapping of a real vehicle on a physical road, for example, including a mapping of elements, such as a location and a driving behavior, of the real vehicle.

Virtual simulated vehicle: For a sensing blank region with no sensed data in a simulation system, to avoid absence of a vehicle in the region at a simulation starting moment, a virtual vehicle configured to simulate a real vehicle that may exist in the sensing blank region is generated in the simulation system according to historical data of the region or a basic traffic graph.

With the research and progress of the AI technology, the AI technology is studied in and applied to a plurality of fields such as a common smart home, a smart wearable device, a virtual assistant, a smart speaker, smart marketing, unmanned driving, autonomous driving, an unmanned aerial vehicle, a robot, smart medical care, and smart customer service. It is believed that with the development of technologies, the AI technology will be applied to more fields, and play an increasingly important role. In the embodiments of the present disclosure, the AI can be configured to generate an autonomous driving model. The autonomous driving model represents a comprehensive algorithm module having decision planning and control execution functions.

A digital twin is a technical means of digitally creating a virtual entity of a physical entity, and simulating, performing verification on, predicting, and controlling a whole life cycle process of the physical entity by using historical data, real-time data, an algorithm model, and the like. The digital twin can establish a virtual parallel world for a road, completely map elements, such as an environment, a vehicle, and an incident, of a physical world of the road in real time, and performing full sensing and dynamically monitoring through data of sensors distributed in the road, to form an accurate information expression and mapping of the physical road by the virtual road in an formation dimension, so that management personnel can still grasp an overall status of the road without being located at a site of the road, thereby resolving the problems such as difficult detection of a whole road segment, delayed incident discovery, and difficult post incident analysis. The digital twin not only has a simulation capability, but also has prediction and control capabilities. In the embodiments of the present disclosure, the digital twin may be configured to generate a simulated road including ramps and a simulated environment corresponding to the simulated road.

In a road segment region that can be covered by sensors, information acquired by multi-dimensional traffic facilities, such as video cameras or radars, are self-loaded and fused. Through a target fusion algorithm, original, incoherent target information obtained by various sensors verify and complement each other, to form substantially complete target attribute information. The target attribute information can be used as the sensed data in the embodiments of the present disclosure, and therefore, accurate delineation of a traveling trajectory of a vehicle on a road can be implemented. For example, a target of radar detection is associated with a target of video recognition through an association relationship of a map. In addition, a real-time detection target is superimposed on a high-precision map, to implement a connection between a physical space and a virtual space, and complete holographic sensing of a digital mapping. Further, in a driving simulation system, real-time reproduction simulation can be performed on a sensing region with sensed data in a road, based on which simulation deduction can be performed, to describe, diagnose, predict, and make a decision on core services such as a traffic hazard, a traffic incident, and traffic congestion, achieve real-time, efficient intelligent analysis and active management and control, and finally implement closed-loop control, thereby achieving refinement, intelligence, standardization, and specialization of main road management, and laying a solid foundation for traffic management.

Because not all road segments of a road have sensed data, previously reproduction simulation can be performed on only some regions with sensed data in the road. In this case, an overall status of a road cannot be accurately reproduced. For example, a ramp does not have sensed data, a traffic status in the ramp cannot be reproduced, resulting in reduced accuracy of reproduction of a physical road. In addition, due to low accuracy of reproduction, when a traffic status of a road in a future period of time is predicted, accuracy of prediction on the road is low.

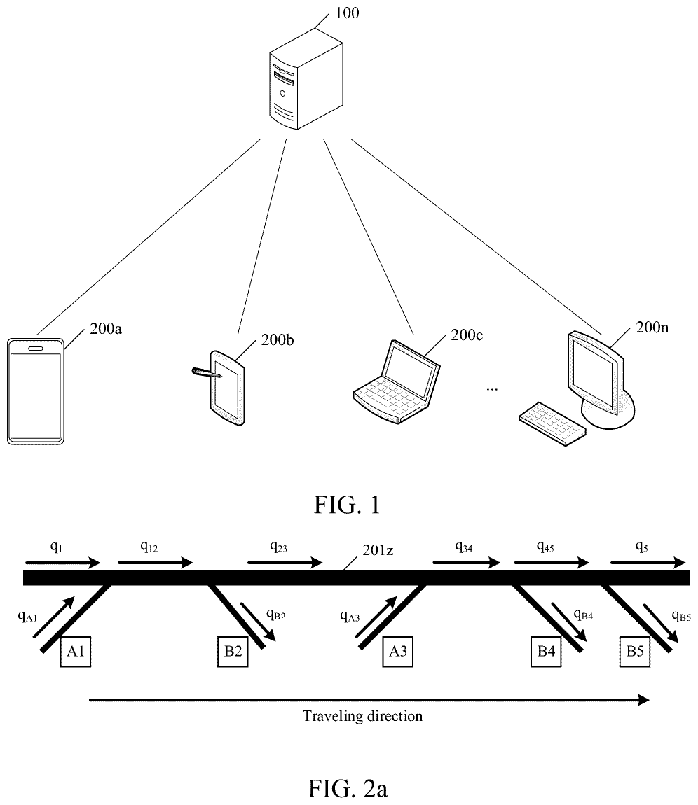

Referring to FIG. 1, FIG. 1 is a schematic architectural diagram of a system according to an embodiment of the present disclosure. As shown in FIG. 1, the system may include a service server 100 and a terminal device cluster. The terminal device cluster may include one or more terminal devices. A quantity of terminal devices is not limited in the present disclosure. As shown in FIG. 1, the terminal device cluster may include a terminal device 200a, a terminal device 200b, a terminal device 200c, . . . , and a terminal device 200n.

There may be communication connections between terminal devices. For example, there is a communication connection between the terminal device 200a and the terminal device 200b, and there is a communication connection between the terminal device 200a and the terminal device 200c. In addition, any terminal device in the terminal device cluster may have a communication connection with the service server 100. For example, there is a communication connection between the terminal device 200a and the service server 100. Connection manners of the communication connections are not limited. Direct or indirect connections may be performed in a wired communication manner, a wireless communication manner, or another manner, which is not limited in the present disclosure.

An application client may be installed on each terminal device in the terminal device cluster shown in FIG. 1. When running on the terminal devices, the application client may exchange data with the service server 100 shown in FIG. 1 through the foregoing communication connections respectively. The application client may be an application client having a function of loading a simulated ramp, such as a video application, a live streaming application, a social application, an instant messaging application, a game application, a navigation application, a map application, or a browser. The application client may be an independent client, or may be an embedded sub-client integrated in a specific client (for example, a social client, an education client, and a multimedia client), which is not limited herein.

Using a navigation application as an example, the service server 100 may be a set of a plurality of servers including a backend server corresponding to a navigation application, a data processing server, and the like. Therefore, each terminal device may perform data transmission with the service server 100 through an application client corresponding to the navigation application. For example, each terminal device may upload a road vehicle prediction request for a simulated road to the service server 100 through an application client of a navigation application. Further, the service server 100 may perform vehicle prediction on the simulated road according to the road vehicle prediction request, to obtain a predicted simulated driving behavior of a virtual simulated vehicle, and return the predicted simulated driving behavior of the virtual simulated vehicle to the terminal device.

In specific implementations of the present disclosure, related data, such as user information (for example, sensed data and historical data corresponding to a simulated ramp), may be involved. When the embodiments of the present disclosure are applied to a specific product or technology, a permission or an approval from a user needs to be obtained. In addition, collection, use, and processing of the related data need to comply with relevant laws, regulations, and standards of relevant countries and regions.

For ease of subsequent understanding and description, in the embodiments of the present disclosure, one terminal device may be selected from the terminal device cluster shown in FIG. 1 as a target terminal device. For example, the terminal device 200a is used as the target terminal device. When obtaining a road vehicle prediction request for a simulated road, the terminal device 200a may transmit the road vehicle prediction request to the service server 100. The service server 100 obtains a driving simulation system according to the road vehicle prediction request, and generates a simulated road in the driving simulation system. Road content of the simulated road may be divided into two parts, namely, a simulated main road and a simulated ramp for assisting the simulated main road. Further, the service server 100 determines an association relationship between the simulated ramp in the simulated road and sensed data of the simulated road. The sensed data may be real road data, for example, data acquired by sensing devices on a real road side, which may include a driving route and a driving position of a real vehicle, obstacle objects (such as an obstacle vehicle, an obstacle pedestrian, and an obstacle article) around the real vehicle, locations of the obstacle objects, and the like. Not all road segments of the simulated road have sensed data. Because real road data of some road segments is not acquired and processed, sensed data of the road segments is not generated. Therefore, before the driving simulation system is run, it is necessary to determine which road segments have sensed data and which road segments do not have sensed data. In the embodiments of the present disclosure, a road segment with sensed data in the simulated road is referred to as a sensing coverage region, and a road segment without sensed data is referred to as a sensing blank region.

The driving simulation system includes two consecutive simulation stages. The first simulation stage is a simulation reproduction stage, and the second simulation stage is a simulation prediction stage. If an association relationship between sensed data and a simulated ramp indicates that the simulated ramp does not belong to a sensing region (namely, a sensing coverage region) with sensed data, a first virtual simulated vehicle is generated in the simulated ramp before running of the driving simulation system is started (namely, at a simulation starting moment). Because a real vehicle may travel on a real road segment mapped by the simulated ramp, the first virtual simulated vehicle is generated to conform to an actual traffic status of the simulated ramp. When the driving simulation system enters the simulation reproduction stage (that is, starts to run simulation), the service server 100 outputs a virtual simulated driving behavior of a second virtual simulated vehicle in the simulated ramp according to the first virtual simulated vehicle. The second virtual simulated vehicle includes the first virtual simulated vehicle. In addition, the service server 100 outputs a reproduced simulated driving behavior corresponding to sensed data in a sensing coverage region. The reproduced simulated driving behavior is consistent with an actual driving behavior in the sensed data. For example, if information at a moment b in the sensed data is that a real vehicle a decelerates and travels to a right lane, in the driving simulation system, for the sensing coverage region, a reproduced simulated driving behavior at the moment b of a reproduced simulated vehicle corresponding to the real vehicle a decelerates and travels to a right lane. By running the simulation reproduction stage, the service server 100 can determine that a simulated traffic status reproduced in the driving simulation system is highly similar to an actual scenario (in which a simulated traffic status reproduced in the sensing coverage region is consistent with an actual scenario). Therefore, it can be ensured that initial simulation data entering the simulation prediction stage is highly similar to the actual scenario, so that accuracy of a predicted simulated driving behavior outputted by the driving simulation system can be determined.

In the simulation prediction stage later than the simulation reproduction stage, the service server suspends inputting of sensed data. In this case, the driving simulation system performs prediction simulation on all the road segments of the simulated road. Therefore, according to the virtual simulated driving behavior, the service server 100 outputs a predicted simulated driving behavior of a third virtual simulated vehicle in the simulated ramp. In the embodiments of the present disclosure, descriptions for describing simulation by the driving simulation system for a simulated ramp are not for describing or limiting a simulation process of a simulated main road in the simulated road

Subsequently, the service server 100 transmits the predicted simulated driving behavior to the terminal device 200a. After receiving the predicted simulated driving behavior transmitted by the service server 100, the terminal device 200a may display the predicted simulated driving behavior on a corresponding screen thereof. The service server 100 may transmit the predicted simulated driving behavior to the terminal device 200a in real time. For example, each time a simulation step is run, a predicted simulated driving behavior corresponding to the simulation step is transmitted to the terminal device 200a. Alternatively, the service server 100 may transmit the predicted simulated driving behavior to the terminal device 200s after the simulation prediction stage ends. In some embodiments, the service server 100 may further transmit a predicted simulated driving behavior within one update periodicity to the terminal device 200a according to the update periodicity. A manner in which the service server 100 transmits the predicted simulated driving behavior is not limited in the embodiments of the present disclosure, and may be set according to requirements of an actual application scenario.

In some embodiments, if sensed data and a simulated road can be obtained locally on the terminal device 200a, the terminal device 200a can create a driving simulation system locally. A subsequent processing process is consistent with the process in which the service server 100 generates the predicted simulated driving behavior. Therefore, details are not described herein again.
the service server 100, the terminal device 200a, the terminal device 200b, the terminal device 200c, . . . , and the terminal device 200n may all be blockchain nodes in a blockchain network. Data (for example, sensed data) described throughout the present disclosure may be stored. A storage manner may be a manner in which a blockchain node generates a block according to the data and adds the block to a blockchain for storage.

A blockchain is a novel application mode of computer technologies such as distributed data storage, point-to-point transmission, a consensus mechanism, and an encryption algorithm, and is mainly configured to organize data in chronological order and encrypt the data into a ledger, to perform verification on, store, and update the data while preventing the data from being tampered with or forged. The blockchain is essentially a decentralized database. Every node in the database stores a same blockchain. The blockchain network can divide nodes into a core node, a data node, and a light node. The core node, the data node, and the light node jointly form blockchain nodes. The core node is responsible for consensus of the overall blockchain network. In other words, the core node is a consensus node in the blockchain network. A process of writing transaction data in the blockchain network into the ledger may be that the data node or the light node in the blockchain network obtains the transaction data, and transfers the transaction data in the blockchain network (that is, the nodes transfer the transaction data in a manner of a baton) until the consensus node receives the transaction data. The consensus node then packages the transaction data into a block, performs consensus on the block, and write the transaction data to the ledger after the consensus is reached. Sensed data is used herein as an example of the transaction data. After performing consensus on the transaction data, the service server 100 (the blockchain node) generates a block according to the transaction data, and stores the block into the blockchain network. Moreover, for reading the transaction data (that is, the sensed data), the blockchain node may obtain a block including the transaction data from the blockchain network, and further, obtain the transaction data from the block.

The method provided in the embodiments of the present disclosure may be performed by a computer device. The computer device includes, but is not limited to, a terminal device or a service server. The service server may be an independent physical server, or may be a server cluster including a plurality of physical servers or a distributed system, or may be a cloud server providing basic cloud computing services, such as a cloud database, a cloud service, cloud computing, a cloud function, cloud storage, a network service, cloud communication, a middleware service, a domain name service, a security service, a content delivery network (CDN), big data, and an artificial intelligence platform. The terminal device includes, but is not limited to, a mobile phone, a computer, an intelligent voice interaction device, an intelligent household appliance, an in-vehicle terminal, an aircraft, and the like. The terminal device may be connected to the service server directly or indirectly in a wired or wireless manner, which is not limited in the embodiments of the present disclosure.

The method provided in the embodiments of the present disclosure may be embedded in a driving simulation system, for performing space-time simulation deduction on a traffic vehicle on a main road (for example, a highway) with a ramp in a digital twin system. Specifically, before simulation is run, a simulated ramp is initially set, and in each simulation step since the simulation is run, space-time deduction is performed on a simulated vehicle in the driving simulation system, and movement of the simulated vehicle is described.

In the present disclosure, time-space deduction of the simulation has two meanings. “Space” refers to performing movement simulation on a virtual simulated vehicle in a sensing blank region, and “time” refers to simulating a running state of a simulated vehicle in a future period of time after injection of sensed data ends. By combining “time” and “space”, a real-time overall status of a road (including a main road and a ramp) can be determined, and a traffic status within a future period of time can be predicted, so that measures may be taken in advance based on the future traffic status. For example, some proactive preventive management and control measures may be taken in advance, to alleviate impending road congestion. The following describes deduction on a road in terms of “space” and “time”.

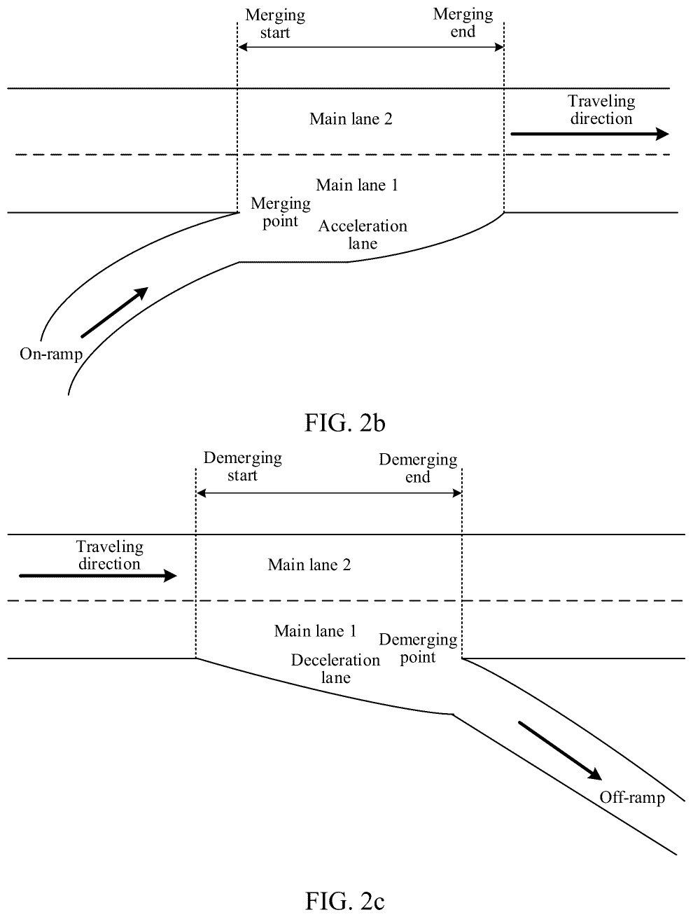

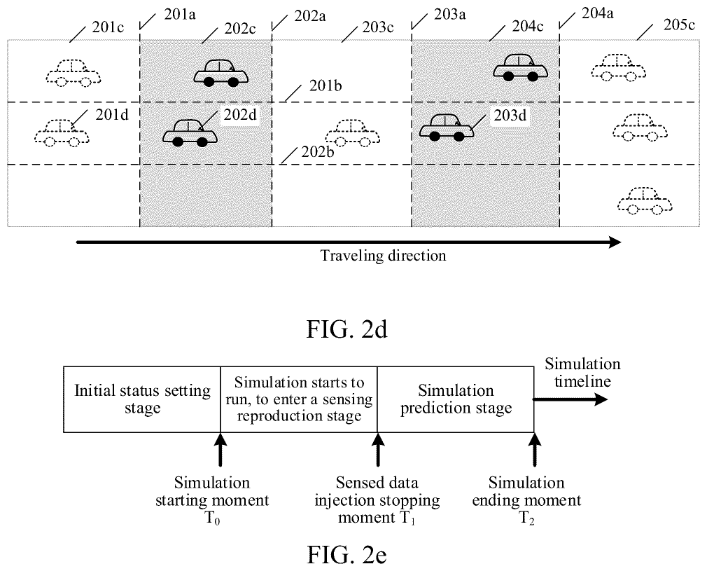

Also referring to FIG. 2a, FIG. 2a is a schematic diagram of a topology of a main road with a ramp according to an embodiment of the present disclosure. An object studied in the present disclosure may be a digital twin system of a main road with a ramp. As shown in FIG. 2a, a road includes a main road 201z and the ramp. A quantity and types of ramps are not limited in this embodiment of the present disclosure, and may be set according to an actual application scenario. In FIG. 2a, a number of a ramp is represented by a number in a square, and an on-ramp is represented by A in a square. For example, in FIG. 2a, A1 represents an on-ramp with a ramp number 1, and A3 represents an on-ramp with a ramp number 3. In FIG. 2a, an off-ramp is represented by B in a square. For example, in FIG. 2a, B2 represents an off-ramp with a ramp number 2, B4 represents an off-ramp with a ramp number 4, and B5 represents an off-ramp with a ramp number 5. The main road may be split into a plurality of main road segments. Each main road segment is determined by ramp numbers. For example, in FIG. 2a, a main road segment 23 represents a main road segment between an off-ramp No. 2 and an on-ramp No. 3, a main road segment 5 represents a downstream main road segment corresponding to an off-ramp No. 5, and a main road segment 1 represents an upstream main road segment corresponding to an on-ramp No. 1. For meanings of other main road segments, reference may be made to the foregoing descriptions. Details are not described again. In this embodiment of the present disclosure, q represents a vehicle flow on a road segment. For example, in FIG. 2a, q_{A3} represents a vehicle flow on an on-ramp No. 3, and q₂₃ represents a vehicle flow on a main road segment between an off-ramp No. 2 and the on-ramp No. 3. For meanings of vehicle flows on other main road segments, reference may be made to the foregoing descriptions. Details are not described again. The vehicle flow may be referred to as a traffic flow, and represents an average quantity of traveling vehicles per unit time of a road segment.

Also referring to FIG. 2b, FIG. 2b is a schematic structural diagram of an on-ramp according to an embodiment of the present disclosure. FIG. 2b shows a merging region of an on-ramp. The merging region includes three parts, namely, mainline lanes (such as a main lane 1 and a main lane 2 shown in FIG. 2b), an acceleration lane parallel to the mainline lanes, and an on-ramp connected to the acceleration lane. A merging start is a line perpendicular to a traveling direction of a lane, and a starting point thereof is a merging point (which may also be understood as a first merging point) at which an upstream main road of the on-ramp is connected to the acceleration lane. A merging end is a line perpendicular to the traveling direction of the lane, and a starting point thereof is a merging point (which may also be understood as a second merging point) at which a downstream main road of the on-ramp is connected to the acceleration lane.

Also referring to FIG. 2c, FIG. 2c is a schematic structural diagram of an off-ramp according to an embodiment of the present disclosure. FIG. 2c shows a demerging region of an off-ramp. The demerging region includes three parts, namely, mainline lanes (such as a main lane 1 and a main lane 2 shown in FIG. 2c), a deceleration lane parallel to the mainline lanes, and an off-ramp connected to the deceleration lane. A demerging start is a line perpendicular to a traveling direction of a lane, and a starting point thereof is a demerging point (which may also be understood as a first demerging point) at which an upstream main road of the off-ramp is connected to the deceleration lane. A demerging end is a line perpendicular to the traveling direction of the lane, and a starting point thereof is a demerging point (which may also be understood as a second demerging point) at which a downstream main road of the off-ramp is connected to the deceleration lane. Bold arrows in FIG. 2b and FIG. 2c all indicate a traveling direction of a vehicle.

In this embodiment of the present disclosure, a system boundary in FIG. 2b and FIG. 2c is set to be an entrance and an exit of a ramp or a mainline without taking an intersection associated with the ramp into account. To be specific, it is considered that a vehicle may enter a main road directly from an on-ramp without first passing through an intersection that is possibly connected to the on-ramp. The vehicle traveling out of an off-ramp is considered to have exited the system without being limited by signal lights at an intersection possibly connected to the off-ramp in reality.

An object studied in the present disclosure may be a digital twin system of a ramp of a road (equivalent to the driving simulation system in this embodiment of the present disclosure). Therefore, a vehicle traveling on the ramp needs to be sensed and simulated. In reality, a sensing device on a road side has a specific coverage range, and the coverage range is limited by a type (such as a millimeter-wave radar or a camera) of the sensing device, a weather condition, and the like. A road includes a main road and a ramp connected to the main road. In this embodiment of the present disclosure, a part of the main road effectively covered by the sensing device is defined as a sensing coverage region, which can ensure that full information of a vehicle in the region can be acquired by the sensing device and uploaded to the driving simulation system as sensed data, for the driving simulation system to completely map and reproduce the information. In this embodiment of the present disclosure, the ramp connected to the sensing coverage region is set to also have sensed data, or it is understood that a sensing region with sensed data includes a sensing coverage region and a ramp connected to the sensing coverage region. Referring to FIG. 2b again, if the upstream main road of the on-ramp has sensed data, the on-ramp is set to also have sensed data. In other words, the sensing region with sensed data includes the on-ramp and the upstream main road of the on-ramp. Referring to FIG. 2c again, if the downstream main road of the off-ramp has sensed data, the off-ramp is set to also have sensed data. In other words, the sensing region with sensed data includes the off-ramp and the downstream main road of the off-ramp.

In this embodiment of the present disclosure, a part of the main road not effectively covered by the sensing device is defined as a sensing blank region. In this embodiment of the present disclosure, the ramp connected to the sensing blank region is set to also have no sensed data, or it is understood that a sensing region with sensed data does not include a sensing blank region and a ramp connected to the sensing blank region. Referring to FIG. 2b again, if the upstream main road of the on-ramp has no sensed data, the on-ramp is set to also have no sensed data. In other words, the sensing region with sensed data does not include the on-ramp and the upstream main road of the on-ramp. Referring to FIG. 2c again, if the downstream main road of the off-ramp has no sensed data, the off-ramp is set to also have no sensed data. In other words, the sensing region with sensed data does not include the off-ramp and the downstream main road of the off-ramp.

Also referring to FIG. 2d, FIG. 2d is a schematic diagram of a scenario of a sensing coverage region and a sensing blank region according to an embodiment of the present disclosure. In an example shown in FIG. 2d, a simulated main road includes three sensing blank regions and two sensing coverage regions. The three sensing blank regions are a sensing blank region 201c, a sensing blank region 203c, and a sensing blank region 205c respectively. The two sensing coverage regions are a sensing coverage region 202c and a sensing coverage region 204c respectively. Simulated vehicles in the three sensing blank regions may all be understood as virtual simulated vehicles. For example, a simulated vehicle 201d is a virtual simulated vehicle. Before the driving simulation system enters the simulation prediction stage, simulated vehicles in the two sensing coverage regions are all generated according to sensed data. Therefore, the simulated vehicles may be understood as reproduced simulated vehicles. For example, a simulated vehicle 202d is a reproduced simulated vehicle. In the example shown in FIG. 2d, the simulated main road includes three simulated lanes, where both a dashed line 201b and a dashed line 202b are lane dividing lines.

A boundary between the sensing blank region 201c and the sensing coverage region 202c may be defined as an upper sensing boundary 201a. A boundary between the sensing coverage region 202c and the sensing blank region 203c may be defined as a lower sensing boundary 202a. A boundary between the sensing blank region 203c and the sensing coverage region 204c may be defined as an upper sensing boundary 203a. A boundary between the sensing coverage region 204c and the sensing blank region 205c may be defined as a lower sensing boundary 204a. The upper sensing boundary and the lower sensing boundary in the simulated main road are both line segments perpendicular to a lane direction (that is, a traveling direction) in a reference line coordinate system (ST coordinate system for short). Simulation performed in the sensing coverage region is defined as reproduction simulation. To be specific, sensed vehicle information is completely reproduced to the driving simulation system in real time. However, for the sensing blank region, virtual simulation in space needs to be performed according to existing information. In this embodiment of the present disclosure, the virtual simulation of the sensing blank region is not limited, and may be set according to an actual application scenario.

In a micro traffic simulation system, each time a simulation clock advances, a speed, a location, and the like of a simulated vehicle in the driving simulation system are updated once. A driving behavior of the simulated vehicle may be described by a micro driving behavior model (equivalent to the autonomous driving model in the present disclosure) such as following and lane changing. In a digital twin simulation system, simulation may be divided into the following stages in terms of a timeline. Also referring to FIG. 2e, FIG. 2e is a diagram of an example of simulation deduction of a simulated main road for “time” according to an embodiment of the present disclosure. As shown in FIG. 2e, an initial status setting stage includes: In FIG. 2e, a simulation starting moment is represented by TO. At this moment, an initial status of simulation starting to run needs to be set, including a real vehicle sensed in the sensing coverage region at the simulation starting moment, and an initial simulated vehicle in the sensing blank region. When the initial status at the moment TO is set, vehicles are filled upward/downstream provided that a range of a map is not exceeded. Alternatively, a maximum quantity of vehicles that can be filled in each region may be limited. During vehicle filling, the vehicle filling can be stopped when the maximum number is reached. A vehicle spacing D during filling and a headway generated in a vehicle outputting region may be random numbers conforming to a distribution. Random seeds may be separately defined, to ensure consistency of random numbers during a plurality of simulations.

Sensing reproduction stage: After a digital twin simulation starts to run, a sensing device transmits vehicle information (statuses such as a location, a speed, and an attitude) in a sensing coverage region to the driving simulation system in real time, and the vehicle information is reproduced and displayed in the driving simulation system. A virtual simulated vehicle in a sensing blank region is also simulated through a corresponding autonomous driving model.

Simulation prediction stage: The digital twin simulation system may perform deduction simulation to predict a traffic status within a future period of time. In FIG. 2e, a moment at which deduction starts is represented by T1. To be specific, starting from this moment, injection of sensed data into the driving simulation system is stopped. The driving simulation system enters the simulation deduction stage, runs simulation based on a traffic status at the moment T1, and predicts, from the simulation, a traffic status within a future period of time. If a moment at which the simulation ends is represented by T2, prediction-deduction of the simulation is performed between T1 and T2. In this stage, no sensed data is injected in real time, and all vehicles in the system are simulated according to a preset model.

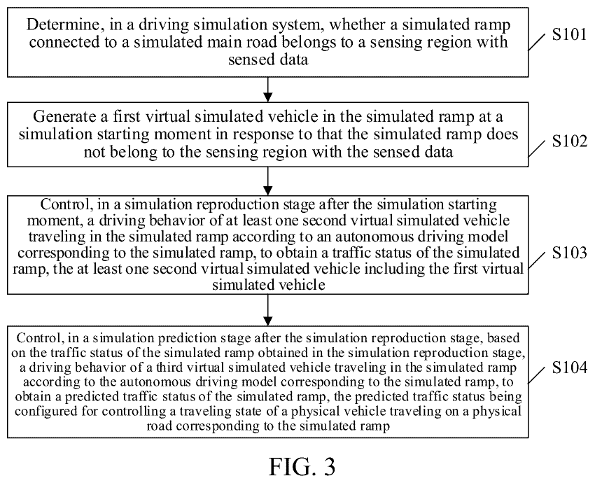

The ramp itself has two states: covered by a sensing device or not covered by a sensing device, that is, with sensed data or without sensed data. A process of “time”−“space” deduction on a ramp is described below through embodiments respectively corresponding to FIG. 3 to FIG. 15.

Referring to FIG. 3, FIG. 3 is a schematic flowchart of a data processing method according to an embodiment of the present disclosure. This embodiment of the present disclosure is applicable to various scenarios, including, but not limited to, the cloud technology, artificial intelligence, intelligent transportation, assisted driving, and the like. This embodiment of the present disclosure is applicable to service scenarios, such as a route searching scenario, a route recommendation scenario, and a route navigation scenario, for a ramp. Specific service scenarios are not enumerated herein. The data processing method may be performed by a service server (for example, the service server 100 shown in FIG. 1), or may be performed by a terminal device (for example, the terminal device 200a shown in FIG. 1), or may be performed by the service server and the terminal device interactively. For ease of understanding, this embodiment of the present disclosure is described by using an example in which the method is performed by a service server. As shown in FIG. 3, the data processing method may include at least the following operations S101 to S104.

S101: Determine, in a driving simulation system, whether a simulated ramp connected to a simulated main road belongs to a sensing region with sensed data.

Specifically, the service server determines a road that needs to be simulated, and obtains a simulated road corresponding to the road in the driving simulation system. The road involved in this embodiment of the present disclosure refers to a main road with a ramp, for example, a highway. Further, the service server determines which regions in the simulated road have sensed data and which regions in the simulated road do not have sensed data. A road segment with sensed data in the simulated main road is referred to as a sensing coverage region, and a road segment without sensed data not overlapping the sensing coverage region in in the simulated main road is referred to as a sensing blank region. Similarly, the simulated ramp may also be divided into two types, namely, a simulated ramp with sensed data, connected to a sensing coverage region, and a simulated ramp without sensed data, connected to a sensing blank region. The simulated ramp with sensed data belongs to a sensing region with sensed data, and the simulated ramp without sensed data does not belong to the sensing region with the sensed data.

For ease of description, in this embodiment of the present disclosure, the sensing region with the sensed data is referred to as a first sensing region. The first sensing region may include the foregoing sensing coverage region and a simulated ramp connected to the sensing coverage region. In this embodiment of the present disclosure, a region of the simulated road other than the first sensing region is referred to as a second sensing region, that is, a sensing region without sensed data. The second sensing region may include the sensing blank region and a simulated ramp connected to the sensing blank region.

Different simulated roads have different lengths, different road-side sensing devices, and different corresponding ramps. A quantity and lengths of simulated ramps are not limited in the embodiments of the present disclosure, and are to be set according to an actual application scenario provided that this embodiment of the present disclosure satisfies conditions of at least one sensing coverage region, at least one sensing blank region, and a simulated ramp connected to the sensing blank region.

The simulated ramp described above is obtained by simulating a ramp in a real road, and is, for example, a ramp in a road in a digital twin system. In this scenario, the sensed data may be real road data acquired by a real road-side sensing device. In addition, in the examples of the present disclosure, real-time performance of the real road data is not limited, and the real road data may be real-time real road data or real road data played back. In some embodiments, the sensed data may be virtual road data, for example, virtual road data set by the service server for predicting whether a vehicle collision will occur on a real road. In another feasible solution, the simulated road may alternatively be a virtual road. In this scenario, the sensed data is virtual road data. As described above, in this embodiment of the present disclosure, sources of the simulated road and the sensed data are not limited, and may be set according to requirements of an actual application scenario.

S102: Generate a first virtual simulated vehicle in the simulated ramp at a simulation starting moment in response to that the simulated ramp does not belong to the sensing region with the sensed data.

At the simulation starting moment, initialization needs to be performed for the second sensing region without sensed data, that is, to fill the simulated road with virtual simulated vehicles.

Specifically, for a simulated ramp belonging to the second sensing region without sensed data, if historical data corresponding to the simulated ramp is not an empty set, historical data corresponding to the simulation starting moment is obtained from the historical data corresponding to the simulated ramp as a first starting traffic status corresponding to the simulated ramp, and the first virtual simulated vehicle is generated in the simulated ramp according to the first starting traffic status, that is, the simulated ramp is filled with the first virtual simulated vehicle, to initialize the simulated ramp. A second starting traffic status corresponding to the simulated ramp is determined according to a target traffic status in a basic traffic graph corresponding to the simulated ramp if the historical data corresponding to the simulated ramp is an empty set, and the first virtual simulated vehicle is generated in the simulated ramp according to the second starting traffic status.

A specific process of generating the first virtual simulated vehicle in the simulated ramp according to the first starting traffic status includes determining an average vehicle spacing corresponding to the simulated ramp according to a vehicle density in the first starting traffic status; and generating, if the simulated ramp is a simulated on-ramp, one or more first virtual simulated vehicles in the simulated on-ramp in sequence, according to the average vehicle spacing, by tracking back from a merging point of the simulated on-ramp toward an upstream direction of the simulated on-ramp (that is, tracking back in a direction opposite to a traveling direction of the simulated on-ramp). In some embodiments, the merging point is a meeting point at which the simulated on-ramp merges into the main road.

For the first sensing region with sensed data, the service server may obtain starting sensed data of the first sensing region at the simulation starting moment from the sensed data, and then generate a starting reproduced simulated vehicle in the first sensing region according to the starting sensed data. If there are a plurality of sensing coverage regions in total, each sensing coverage region is processed independently. Referring to FIG. 2d again, it is set that FIG. 2d is a schematic diagram of a scenario at the simulation starting moment. In this case, the driving simulation system generates, according to starting sensed data corresponding to the sensing coverage region 202c, a starting reproduced simulated vehicle, such as the simulated vehicle 202d shown in FIG. 2d, in the sensing coverage region 202c. The driving simulation system generates, according to starting sensed data corresponding to the sensing coverage region 204c, a starting reproduced simulated vehicle, such as the simulated vehicle 203d shown in FIG. 2d, in the sensing coverage region 204c.

Similarly, if there are a plurality of simulated ramps in the first sensing region in total, each simulated ramp is processed independently. Referring to FIG. 2d again, assuming that a first simulated ramp is connected to the sensing coverage region 202c, the driving simulation system generates a starting reproduced simulated vehicle in the first simulated ramp according to the starting sensed data corresponding to the first simulated ramp. Assuming that a second simulated ramp is connected to the sensing coverage region 204c, the driving simulation system generates a starting reproduced simulated vehicle in the second simulated ramp according to the starting sensed data corresponding to the second simulated ramp.

Before the driving simulation system is run, for the second sensing region, a virtual simulated vehicle needs to be initialized at the simulation starting moment, to avoid a “hollow” road segment without a vehicle in a road network at the simulation starting moment. In this embodiment of the present disclosure, the descriptions of the simulation of the sensing blank region are not limited, and may be set according to an actual application scenario.

If there are a plurality of simulated ramps in the second sensing region in total, each simulated ramp is processed independently. As shown in FIG. 2d, if the sensing blank region 201c, the sensing blank region 203c, and the sensing blank region 205c are each connected to a simulated ramp, for example, a third simulated ramp, a fourth simulated ramp, and a fifth simulated ramp, the driving simulation system processes the third simulated ramp, the fourth simulated ramp, and the fifth simulated ramp independently. A processing process of the simulated ramp in the second sensing region at the simulation starting moment is as follows.

As described above in FIG. 2a, the simulated ramp may be divided into a simulated on-ramp and a simulated off-ramp. For the simulated on-ramp, the service server determines whether the simulated on-ramp has historical data, that is, whether historical data (first historical data for short) corresponding to the simulated on-ramp is an empty set. If the first historical data is not an empty set, the service server obtains historical data corresponding to the simulation starting moment from the first historical data as a first starting traffic status corresponding to the simulated on-ramp. The first starting traffic status includes a vehicle flow, a vehicle density, and a vehicle speed of the simulated on-ramp at the simulation starting moment. Further, according to the vehicle density in the first starting traffic status, the service server may determine an average vehicle spacing D1, that is, a distance between two virtual simulated vehicles corresponding to the simulated on-ramp. The service server generates a normal distribution N(D1, σ²) with the average vehicle spacing D1 as a mean. In this embodiment of the present disclosure, a specific distribution and a specific variance are not limited provided that diversity is ensured.

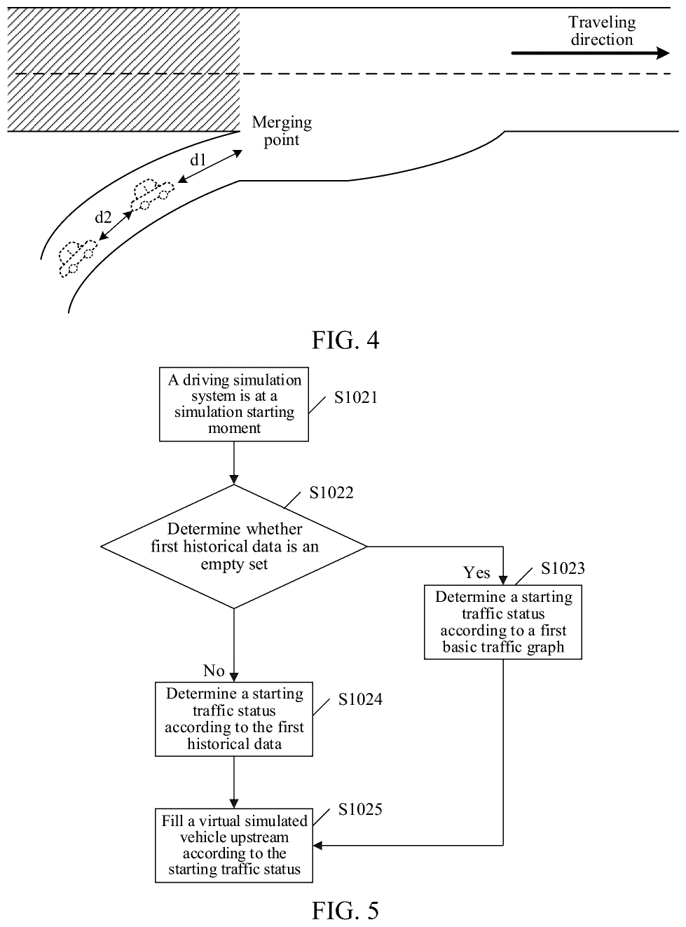

Also referring to FIG. 4, FIG. 4 is a schematic diagram of a scenario of generating a first virtual simulated vehicle in a simulated on-ramp according to an embodiment of the present disclosure. The service server searches for a distance di (a random value conforming to a normal distribution N(D1, σ²)) upstream of the simulated on-ramp starting from a merging point of the simulated on-ramp as a location in the simulated on-ramp at which a virtual vehicle needs to be filled and generates vehicle spacings dj (j=i, i+1, . . . ) in sequence for filling virtual simulated vehicles upstream, for example, a vehicle spacing d1 to a vehicle spacing d2, as shown in FIG. 4. An order of filling is not limited in this embodiment of the present disclosure, and may be performed in order by lanes, that is, one lane is filled up first, and then another lane is filled, or a plurality of lanes close to a merging point may be filled first, and then backtracking is performed upstream. When a selected vehicle spacings dj exceeds a range of the simulated on-ramp (namely, an upstream edge of the simulated on-ramp) after being extended upstream, the service server determines that initialization on this lane of the simulated on-ramp is completed.

If the first historical data is an empty set, the service server randomly obtains, according to a basic traffic graph (first basic traffic graph for short) corresponding to the simulated on-ramp, a vehicle density in a free traveling state (equivalent to the target traffic status) in the first basic traffic graph. According to the vehicle density, the service server determines an average vehicle spacing D2 of the simulated on-ramp at the simulation starting moment. A subsequent process is the same as a process in which the service server fills the simulated on-ramp with a virtual simulated vehicle (namely, the first virtual simulated vehicle) according to the average vehicle spacing D1. Therefore, details are not described herein again, and reference may be made to the foregoing description.

Referring to FIG. 4 again, if the simulated on-ramp does not have sensed data, or the first sensing region does not include the simulated on-ramp in FIG. 4, an upstream main road of the simulated on-ramp, that is, a dashed region in FIG. 4, also does not have sensed data.

For a process in which the service server generates the first virtual simulated vehicle in the simulated on-ramp at the simulation starting moment, reference may also be made to FIG. 5. FIG. 5 is a schematic flowchart of a method for generating a virtual simulated vehicle for a simulated on-ramp at a simulation starting moment according to an embodiment of the present disclosure. As shown in FIG. 5, the method may include the following operations:
S1021: A driving simulation system is at a simulation starting moment.
S1022: Determine whether first historical data is an empty set. In a scenario in which the first historical data is an empty set, the service server performs S1023. In a scenario in which the first historical data is not an empty set, the service server performs S1024.
S1023: The service server determines a starting traffic status, that is, the foregoing second starting traffic status, corresponding to the simulated on-ramp according to the first basic traffic graph.
S1024: The service server determines a starting traffic status, that is, the foregoing first starting traffic status, corresponding to the simulated on-ramp according to the first historical data.
S1025: The service server fills a virtual simulated vehicle upstream according to the starting traffic status. The virtual simulated vehicle generated in the simulated ramp at the simulation starting moment is referred to as a first virtual simulated vehicle in the present disclosure.

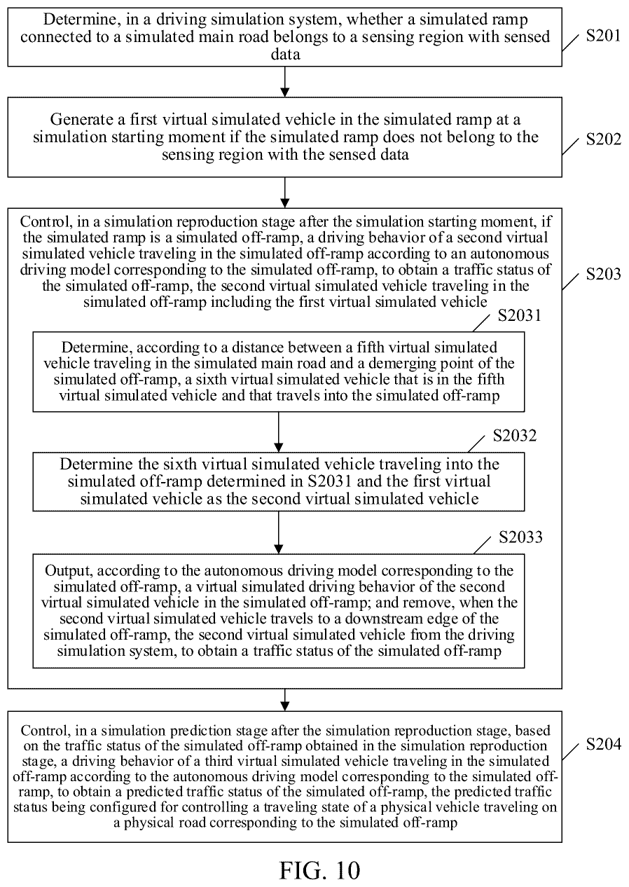

For descriptions of the simulated off-ramp, reference may be made to the following descriptions in the embodiment corresponding to FIG. 10.

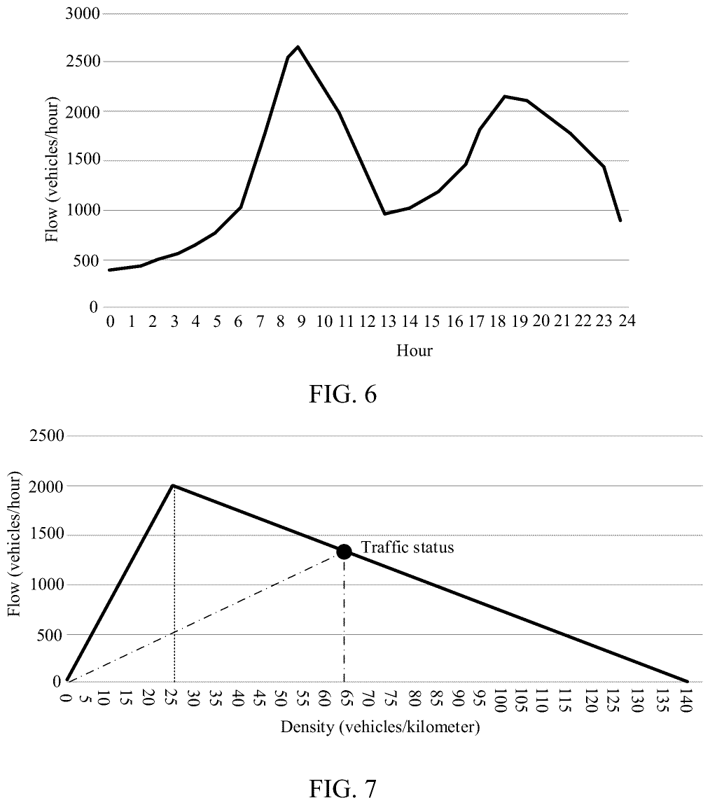

On an actual road, such as a highway, a sensing device coverage rate may not be high. To be specific, real-time vehicle trajectory data cannot cover all road segments of the highway that need to be simulated. In a road segment not covered by a sensing device, it is first determined whether there is a historical traffic status described by historical data. The historical data may include data, such as an average vehicle flow/an average vehicle density/an average vehicle speed, acquired by a checkpoint device. Also referring to FIG. 6, FIG. 6 is a diagram of an example of a broken line of an average vehicle flow according to an embodiment of the present disclosure. FIG. 6 shows a diagram of a broken line of an average flow for 24 hours. In some embodiments, a time granularity may be on the order of minutes, 5 minutes, 10 minutes, 15 minutes, and 30 minutes to the order of hours. According to classification of data sources, there may also be similar data curves for the vehicle density and the average speed. After simulation is run, the service server may perform some settings for current simulation based on historical data.

In this embodiment of the present disclosure, historical data corresponding to different sensing regions is independent. For example, historical data (that is, the foregoing first historical data) corresponding to the simulated on-ramp and historical data (second historical data for short) corresponding to the simulated off-ramp are independent of each other. Therefore, the first historical data may be the same as the second historical data, or the first historical data may be different from the second historical data. In some application scenarios, the first historical data may exist, but the second historical data does not exist.

If the historical data is a time-varying curve (shown in FIG. 6) that changes with time, assignments may also be set separately according to a time of the simulation. For example, during deduction, if the historical data is an average vehicle flow, an average vehicle density, an average vehicle speed, and the like every 15 minutes, the time of the simulation may be set accordingly. To be specific, a parameter that needs to be set is correspondingly adjusted every 15 minutes, to be consistent with the historical data as much as possible.

In the traffic flow theory, the basic traffic graph may describe relationships between a macro vehicle flow, a vehicle density, and a vehicle speed in a traffic network. Also referring to FIG. 7, FIG. 7 is a schematic diagram of a basic traffic graph according to an embodiment of the present disclosure. A horizontal axis of the basic traffic graph represents a vehicle density, and a vertical axis represents a vehicle flow. The basic traffic graph may be approximated into two straight line segments that form a triangle with a horizontal axis. Each point on the straight line segments represents a traffic status. The first straight line segment describes a free traveling state of a vehicle, referred to as a target traffic status in this embodiment of the present disclosure. A slope of the first straight line segment is a free-flow vehicle speed Vₘₐₓ, illustrated by 80 kilometers per hour in FIG. 7. In a process in which the vehicle density increases from 0 to a critical density K_{cr} (illustrated by 25 vehicles/kilometer in FIG. 7), the free-flow vehicle speed does not change, and a traffic capacity (that is, the vehicle flow) gradually increases, and reaches a maximum traffic capacity Qₘₐₓ (illustrated by 2000 vehicles/hour in FIG. 7) at the critical density K_{cr}. When the density continues to increase due to the continuous increase of vehicles, the vehicle speed gradually reduces, to enter a congested state, and the traffic capacity also decreases accordingly, as indicated by the second straight line segment. When the vehicle density increases to a congestion density Kⱼₐₘ (illustrated by 140 vehicles/kilometer in FIG. 7), the traffic enters a completely-congested stop state, and the vehicle speed and the traffic capacity are both reduced to 0.

The congestion density Kⱼₐₘ in the basic traffic graph depends on only a vehicle head-to-vehicle head distance when the traffic is completely congested. The maximum traffic capacity Qₘₐₓ and the free flow speed are parameters related to a road type, and may be obtained through parameter correction or querying related specifications. The two straight line segments in the basic traffic graph can be uniquely determined based on the three parameters. A manner of obtaining the basic traffic graph is not limited herein. The basic traffic graph may be defined by giving the foregoing parameters in a scenario file. Alternatively, basic traffic attributes of different types of roads may be defined by setting different default basic traffic graphs in the simulation system.

In a case that a vehicle density is given, according to the basic traffic graph, the service server may uniquely determine a traffic status of a vehicle, to determine a speed of the traffic. A spacing D between centroids of vehicles and a traffic density K are in a reciprocal relationship. Therefore, when the traffic density K is given, the service server can calculate an initial vehicle spacing D and a speed V of a vehicle.

In this embodiment of the present disclosure, basic traffic graphs corresponding to different sensing regions are independent. For example, a basic traffic graph (first basic traffic graph for short) corresponding to the simulated on-ramp and a basic traffic graph (second basic traffic graph for short) corresponding to the simulated off-ramp are independent of each other. Therefore, the first basic traffic graph may be the same as the second basic traffic graph, or the first basic traffic graph may be different from the second basic traffic graph.

Before the simulation is run, a manager may be enabled to set default parameters such as a free-flow vehicle speed Vₘₐₓ, a congestion density Kⱼₐₘ, a critical density K_{cr}, and a maximum traffic capacity Qₘₐₓ, or use default values, to generate a basic traffic graph. The basic traffic graph may also be referred to as a macro basic graph.

When a virtual simulated vehicle needs to be generated, the service server may back-calculate the traffic density K based on the vehicle spacing D and by using a reciprocal of the vehicle spacing D. Therefore, a traffic status (a flow, a speed, a density, and the like) may be uniquely determined from the basic traffic graph, to obtain an initial speed and a headway of the virtual simulated vehicle. For a relationship between the vehicle spacing D and the traffic density K (that is, the vehicle density), reference may be made to the following formula (1). An initial speed V of a vehicle may be determined through a formula (2).

$$D = 1 / K \qquad ( 1 )$$

$$\begin{matrix}V = {V}_{max} & ( K \leq {K}_{c r} ) \\ V = ( K {Q}_{max} / ( {K}_{c r} - {K}_{j a m} ) + {k}_{j a m} {Q}_{max} / ( {K}_{j a m} - {K}_{c r} ) ) / K & ( K > {K}_{c r} )\end{matrix} \qquad ( 2 )$$

S103: Control, in a simulation reproduction stage after the simulation starting moment, a driving behavior of at least one second virtual simulated vehicle traveling in the simulated ramp according to an autonomous driving model corresponding to the simulated ramp, to obtain a traffic status of the simulated ramp, the at least one second virtual simulated vehicle including the first virtual simulated vehicle.

At the simulation starting moment, the first virtual simulated vehicle has been filled in the simulated ramp. After the simulation starts to run (entering the simulation reproduction stage), the initially filled first virtual simulated vehicles control driving behaviors thereof according to the autonomous driving model corresponding to the simulated ramp.

Specifically, if the simulated ramp is a simulated on-ramp, the at least one second virtual simulated vehicle traveling in the simulated ramp includes the first virtual simulated vehicle generated at the simulation starting moment and a virtual simulated vehicle (hereinafter referred to as a fourth virtual simulated vehicle) generated in the simulation reproduction stage. A process of generating the fourth virtual simulated vehicle in the simulation reproduction stage is as follows: determining a first vehicle generation sub-region (or referred to as a vehicle outputting region) in the simulated on-ramp, the vehicle outputting region being a region that is in the simulated on-ramp and that is configured for randomly generating a virtual simulated vehicle, and the vehicle outputting region being located between a first vehicle generation line (also referred to as a vehicle outputting line) and an upstream edge of the simulated on-ramp, the first vehicle generation line being perpendicular to a traveling direction of the simulated on-ramp; generating the first vehicle generation sub-region (also referred to as a vehicle outputting region) in the simulated on-ramp according to the upstream edge of the simulated on-ramp and the first vehicle generation line; generating the fourth virtual simulated vehicle in the first vehicle generation sub-region, the first virtual simulated vehicle and the fourth virtual simulated vehicle being collectively referred to as a second virtual simulated vehicle below; outputting, according to the autonomous driving model corresponding to the simulated on-ramp, a virtual simulated driving behavior of the second virtual simulated vehicle in the simulated on-ramp.

A specific process of generating the fourth virtual simulated vehicle in the first vehicle generation sub-region (the vehicle outputting region) may include: obtaining, if historical data corresponding to the simulated on-ramp is not an empty set, historical data corresponding to the simulation reproduction stage from the historical data corresponding to the simulated on-ramp as a first reproduced traffic status corresponding to the simulated on-ramp, and generating the fourth virtual vehicle in the first vehicle generation sub-region according to the first reproduced traffic status; and determining, if the historical data corresponding to the simulated on-ramp is an empty set, a second reproduced traffic status corresponding to the simulated on-ramp according to the target traffic status in the basic traffic graph corresponding to the simulated on-ramp, and generating the fourth virtual vehicle in the first vehicle generation sub-region according to the second reproduced traffic status.

S103 may further include: obtaining an initial autonomous driving model corresponding to the simulated on-ramp; adjusting, if historical data corresponding to the simulated on-ramp is not an empty set, a parameter in the initial autonomous driving model corresponding to the simulated on-ramp according to the historical data corresponding to the simulated on-ramp, to obtain the autonomous driving model corresponding to the simulated on-ramp; and adjusting, if historical data corresponding to the simulated on-ramp is an empty set, a parameter in the initial autonomous driving model corresponding to the simulated on-ramp according to a road type corresponding to the simulated on-ramp, to obtain the autonomous driving model corresponding to the simulated on-ramp.

S103 may further include: generating, if a sensing coverage region exists in a downstream region of the simulated on-ramp, a vehicle withdrawing line at an upstream edge of the sensing coverage region, the vehicle withdrawing line being perpendicular to a traveling direction of the simulated road and also referred to as a first vehicle removal line, the downstream region of the simulated on-ramp belonging to the simulated main road, and the sensing coverage region belonging to the sensing region with the sensed data; removing, from the driving simulation system, a virtual simulated vehicle that is one of the at least one second virtual simulated vehicle and that travels to the first vehicle removal line; and removing, if no sensing coverage region exists in the downstream region of the simulated on-ramp, the second virtual simulated vehicle from the driving simulation system when the second virtual simulated vehicle travels to a downstream edge (for example, a map edge) of the simulated main road.

S103 may further include: determining, as a downstream vehicle (which may also be referred as a first vehicle) in the simulated on-ramp, a virtual simulated vehicle that is one of the at least one second virtual simulated vehicle and that is closest to a downstream edge of the simulated on-ramp; determining a maximum vehicle speed of the downstream vehicle according to historical data corresponding to the simulated on-ramp; determining a virtual simulated vehicle other than the downstream vehicle in the at least one second virtual simulated vehicle as an upstream vehicle in the simulated on-ramp; and determining a maximum vehicle speed of the upstream vehicle according to a road type corresponding to the simulated on-ramp. Then, a specific process of outputting, according to the autonomous driving model corresponding to the simulated on-ramp, a virtual simulated driving behavior of the at least one second virtual simulated vehicle in the simulated on-ramp may include: controlling the virtual simulated driving behavior of the at least one second virtual simulated vehicle traveling in the simulated on-ramp according to the autonomous driving model corresponding to the simulated on-ramp, the maximum vehicle speed of the upstream vehicle, and the maximum vehicle speed of the downstream vehicle.

After the driving simulation system starts to run, the service server inputs sensed data to the driving simulation system. The driving simulation system outputs, according to the sensed data, a reproduced simulated vehicle and a vehicle trajectory, that is, a reproduced simulated driving behavior, of the reproduced simulated vehicle in the first sensing region in real time, and reproduces statuses, such as a type, a location, a speed, and an attitude (azimuth angle), of the vehicle in the first sensing region in real time. As a simulation clock continuously advances, the sensed data is continuously injected into the driving simulation system, and the driving simulation system reproduces simulated vehicles with the reproduced simulated driving behavior one by one in the first sensing region.

To maintain authenticity of the simulation effect, for operation of the virtual simulated vehicle in the second sensing region, the service server updates a longitudinal speed and a transverse speed of the virtual simulated vehicle through an autonomous driving model (including a following model and a lane changing model). A simulated main road not covered by a sensing device is not described in this embodiment of the present disclosure. A process of processing a simulated on-ramp not covered by a sensing device is described below.

At the simulation starting moment, a filled initial vehicle, for example, the first virtual simulated vehicle in S102 described above, may exist in the simulated on-ramp. After the simulation starts to run, longitudinal and transverse driving behaviors of the first virtual simulated vehicle generated in the simulated on-ramp at the simulation starting moment are simulated through an autonomous driving model (including a following model and a lane changing model) corresponding to the simulated on-ramp. In this embodiment of the present disclosure, the autonomous driving model corresponding to the simulated on-ramp is defined as a first autonomous driving model.

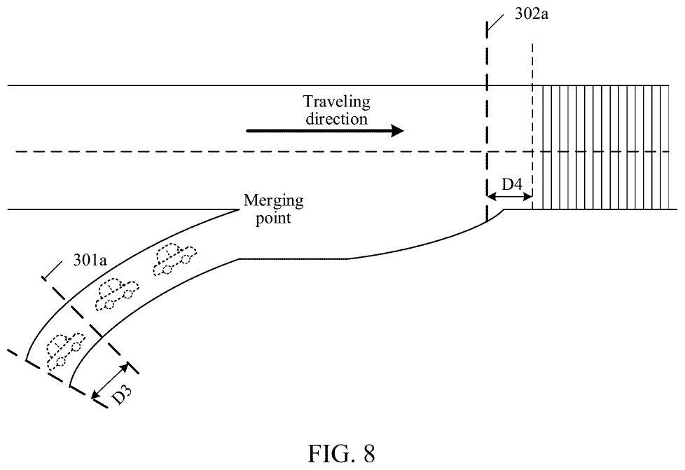

Also referring to FIG. 8, FIG. 8 is a schematic diagram of a scenario of outputting a virtual simulated driving behavior in a simulated on-ramp according to an embodiment of the present disclosure. As shown in FIG. 8, in this embodiment of the present disclosure, a first vehicle generation line 301a is determined in the simulated on-ramp. The first vehicle generation line 301a is at D3 from an upstream edge (mostly, a map edge) of the simulated on-ramp. That is, a distance between the upstream edge of the simulated on-ramp and the first vehicle generation line 301a is D3. The first vehicle generation line 301a is a line segment perpendicular to a lane direction (in the ST coordinate system). A road portion between the first vehicle generation line 301a and the upstream edge of the simulated on-ramp forms a first vehicle generation sub-region. After the simulation starts to run, the service server randomly generates a virtual simulated vehicle on a lane center line of the first vehicle generation sub-region. A location of an initial location of the virtual simulated vehicle in a vehicle outputting region (equivalent to the first vehicle generation sub-region) is not limited herein provided that randomness is maintained. That is, the virtual simulated vehicle is avoided from appearing in the driving simulation system from the same place. In this embodiment of the present disclosure, a virtual simulated vehicle generated in the simulated on-ramp in the simulation reproduction stage is defined as a fourth virtual simulated vehicle.

Referring to FIG. 8 again, if a sensing coverage region, such as a vertical line region in FIG. 8, exists in a downstream main road of the simulated on-ramp, after the simulation starts to run, a simulated vehicle in the sensing coverage region in the downstream main road is reproduced from sensed data. Therefore, a virtual simulated vehicle in the simulated on-ramp cannot be introduced into the sensing coverage region; otherwise, a potential collision or conflict between the vehicles is caused. In this case, the service server needs to set a first vehicle removal line 302a (also referred to as a vehicle withdrawing line). The first vehicle removal line 302a is a line segment perpendicular to a lane direction at a distance D4 from an upstream edge of the sensing coverage region. That is, a distance between the upstream edge of the sensing coverage region and the first vehicle removal line 302a is D4. The first vehicle removal line 302a is defined only when a sensing coverage region exists in the downstream main road of the simulated on-ramp. If no sensing coverage region exists in the downstream main road, the first vehicle removal line 302a does not need to be defined.

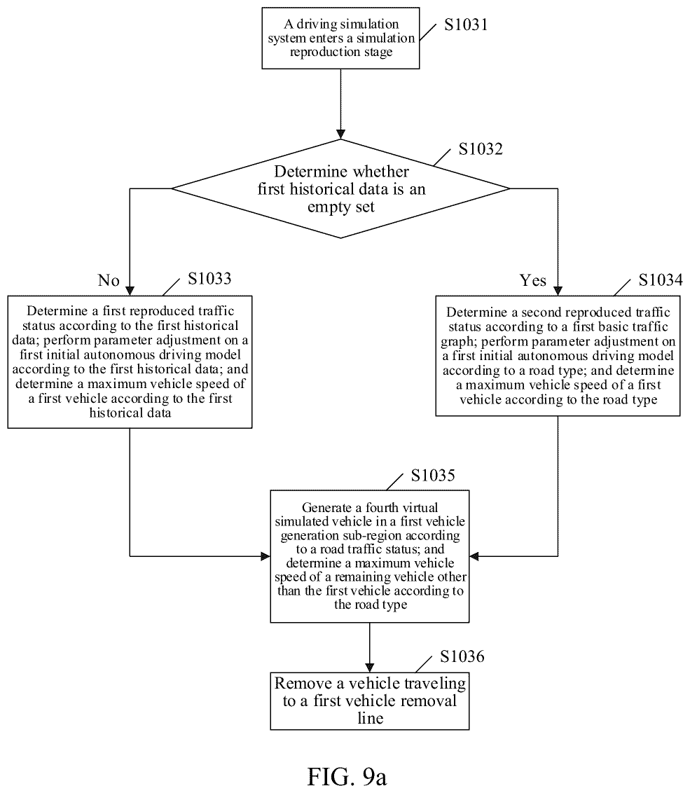

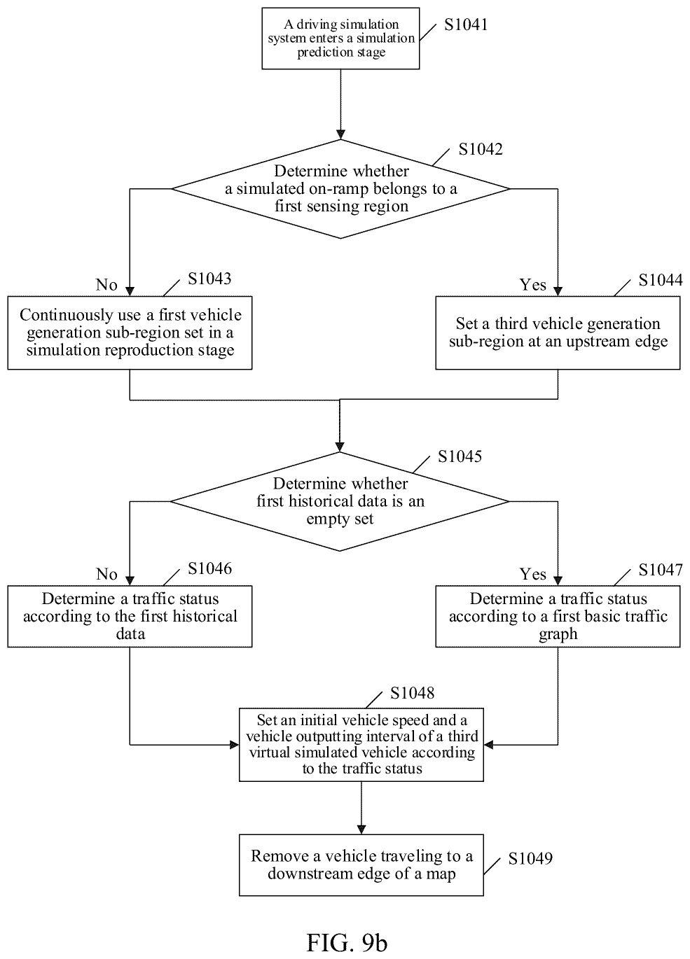

For a processing process of this operation, reference may also be made to FIG. 9a. FIG. 9a is a schematic flowchart of a method for generating a virtual simulated driving behavior for a simulated on-ramp in a simulation reproduction stage according to an embodiment of the present disclosure. As shown in FIG. 9a, the method includes the following operations.
S1031: The driving simulation system enters a simulation reproduction stage.
S1032: The service server determines whether first historical data is an empty set, the first historical data indicating historical data corresponding to the simulated on-ramp; the service server performs S1034 if the first historical data is an empty set; and the service server performs S1033 if the first historical data is not an empty set.
S1033: The service server determines a first reproduced traffic status according to the first historical data; performs parameter adjustment on a first initial autonomous driving model according to the first historical data; and determines a maximum vehicle speed of a first vehicle according to the first historical data. Specifically, a maximum speed of a vehicle entering the driving simulation system from the first vehicle generation sub-region needs to be set. If the first historical data is not an empty set, the service server assigns a value to an initial vehicle speed of the vehicle flow and a value to a vehicle outputting interval between two vehicles according to the first historical data. For example, the initial vehicle speed in the simulation reproduction stage is the same as an average speed corresponding to a period of time associated with the simulation reproduction stage in the first historical data, and the vehicle outputting interval and a vehicle flow corresponding to the period of time associated with the simulation reproduction stage in the first historical data are in a reciprocal relationship. In addition, the service server performs parameter calibration on the first initial autonomous driving model in advance based on the first historical data, so that performance of the first autonomous driving model is similar to the historical data of the simulated on-ramp. The first vehicle in FIG. 9a is equivalent to the foregoing downstream vehicle, for example, the virtual simulated vehicle closest to the merging point in FIG. 8. A last vehicle in FIG. 9a is equivalent to the foregoing upstream vehicle, for example, a virtual simulated vehicle other than the first vehicle in FIG. 8.
S1034: The service server determines a second reproduced traffic status according to a first basic traffic graph; performs parameter adjustment on a first initial autonomous driving model according to a road type; and determines a maximum vehicle speed of the first vehicle according to the road type. Specifically, because the first historical data is an empty set, the service server randomly selects a traffic status in a free driving state (equivalent to the target traffic status) in a basic traffic graph (first basic traffic graph for short) corresponding to the simulated on-ramp, and assigns a value to an initial speed and a value to a vehicle outputting interval. Through the road type, the service server may use default model parameters and determine the maximum vehicle speed of the first vehicle.
S1035: The service server generates a fourth virtual simulated vehicle in the first vehicle generation sub-region according to a road traffic status; and determine a maximum vehicle speed of a remaining vehicle other than the first vehicle according to the road type. After a vehicle enters the driving simulation system from the vehicle outputting region, the first autonomous driving model controls longitudinal and transverse driving behaviors of the vehicle separately. A model type of the first autonomous driving model is not limited in embodiments of the present disclosure.
S1036: The service server removes a vehicle traveling to the first vehicle removal line. Specifically, if a sensing coverage region exists in the downstream main road of the simulated on-ramp, because reproduction simulation in which a real vehicle is sensed exists in the downstream sensing coverage region, a virtual simulated vehicle in the simulated on-ramp is prevented from entering the sensing coverage region. Therefore, when any virtual simulated vehicle (including a filled vehicle existing at an initial moment and a virtual vehicle generated in the vehicle outputting region after the simulation starts to run) reaches the first vehicle removal line, the virtual simulated vehicle is removed from the driving simulation system, to avoid a conflict between the virtual simulated vehicle and a reproduced vehicle in the sensing coverage region. D3 and D4 in FIG. 8 are not limited in this embodiment of the present disclosure. However, D3 is to ensure spatial diversity in initial locations of vehicles appearing in the vehicle outputting region (equivalent to the first vehicle generation sub-region), that is, vehicles are not outputted at a same location. D4 is to ensure that a vehicle in the simulated on-ramp is removed, before entering the sensing coverage region, from the system without causing a conflict. If no sensing coverage region exists in the downstream main road of the simulated on-ramp, the service server removes a vehicle traveling to a lower edge of the map (equivalent to the downstream edge of the simulated road). A confirmation of removing a vehicle hitting the first vehicle removal line or the map edge from the system may be set to a front edge or centroid of the vehicle crossing the line, which is not limited herein.

To ensure continuity of a traffic status, after a vehicle generated in the simulated on-ramp enters the simulated main road, driving simulation is performed on the vehicle by using an autonomous driving model corresponding to the simulated main road, and a maximum vehicle speed is set by using a method corresponding to the simulated main road.

In this operation, a simulated off-ramp is not described in detail, and reference may be made to the following descriptions in the embodiment corresponding to FIG. 10.

S104: Control, in a simulation prediction stage after the simulation reproduction stage, based on the traffic status of the simulated ramp obtained in the simulation reproduction stage, a driving behavior of a third virtual simulated vehicle traveling in the simulated ramp according to the autonomous driving model corresponding to the simulated ramp, to obtain a predicted traffic status of the simulated ramp, the predicted traffic status being configured to control a traveling state of a physical vehicle traveling on a physical road corresponding to the simulated ramp.

Specifically, if the simulated ramp is a simulated on-ramp, a third virtual simulated vehicle is generated in the first vehicle generation sub-region according to historical data corresponding to the simulated on-ramp and a virtual simulated driving behavior. An upstream edge of the first vehicle generation sub-region is equivalent to an upstream edge of the simulated on-ramp. A virtual simulated driving behavior of the third virtual simulated vehicle is outputted in the simulated on-ramp according to an autonomous driving model corresponding to the simulated on-ramp.

After entering the simulation prediction stage, the service server stops injecting sensed data into the driving simulation system. Driving behaviors of all vehicles in the driving simulation system are controlled by a micro traffic model. To be specific, for simulated vehicles in all sensing regions, longitudinal driving behaviors and transverse driving behaviors of the simulated vehicles are controlled by using autonomous driving models respectively corresponding to the sensing regions.

Maximum vehicle speeds of all vehicles (other than the first vehicle on the main road of the entire highway) depend on a road type or a road speed limit. For the first vehicle (that is, a vehicle closest to the downstream edge of the simulated road) in all vehicles in the driving simulation system, it is first checked whether historical data exists in a region in which the first vehicle is located. If the historical data exists, an average vehicle speed corresponding to a period of time associated with the simulation prediction stage in the historical data is assigned to the first vehicle as a maximum vehicle speed. If no historical data exists (which is equivalent to that the historical data is an empty set), the maximum vehicle speed of the first vehicle may be set according to a road type or a road speed limit.

Also referring to FIG. 9b, FIG. 9b is a schematic flowchart of a method for generating a predicted simulated driving behavior for a simulated on-ramp in a simulation prediction stage according to an embodiment of the present disclosure. As shown in FIG. 9b, this operation may be divided into the following operations for execution.
S1041: The driving simulation system enters a simulation prediction stage.
S1042: Determine whether the simulated on-ramp belongs to a first sensing region; perform S1043 if the simulated on-ramp does not belong to the first sensing region, that is, does not have sensed data; and perform S1044 if the simulated on-ramp belongs to the first sensing region, that is, has sensed data.
S1043: Continuously use the first vehicle generation sub-region set in the simulation reproduction stage. The vehicle outputting region, that is, the first vehicle generation sub-region in S103, has been set in the simulated on-ramp in the simulation reproduction stage. In this case, the first vehicle generation sub-region can be continuously used, so that vehicles are continuously generated in this region.
S1044. Set a third vehicle generation sub-region at an upstream edge. In the simulation prediction stage, the service server needs to newly set a vehicle outputting region, which may be referred to as a third vehicle generation sub-region, farthest upstream from the simulated on-ramp and at a distance D5 from the map edge. A process in which the service server generates the third vehicle generation sub-region is the same as a process in which the service server generates the first vehicle generation sub-region.
S1045: Determine whether first historical data is an empty set; perform S1046 if the first historical data is not an empty set; and perform S1047 if the first historical data is an empty set.
S1046: Determine a traffic status according to the first historical data. In the simulation prediction stage, the service server sets, according to the first historical data, an initial speed, a vehicle outputting interval, and the like of a newly generated virtual simulated vehicle in the third vehicle generation sub-region (or the first vehicle generation sub-region). A processing process of the simulated on-ramp in the simulation prediction stage is the same as a processing process of the simulated on-ramp in the simulation reproduction stage. Therefore, a process of generating the virtual simulated vehicle in the simulated on-ramp in the simulation prediction stage and a driving simulation process of the virtual simulated vehicle are not described in detail again. Reference may be made to the foregoing descriptions of S103.
S1047: Determine a traffic status according to a first basic traffic graph. In some embodiments, if the first historical data is an empty set, the service server may set the initial vehicle speed and the vehicle outputting interval by using average values of sensed data in the simulation reproduction stage. For example, the initial speed is the same as an average speed of vehicles sensed in the simulation reproduction stage, and the vehicle outputting interval is the same as an average interval of vehicles sensed in the simulation reproduction stage. If neither a sensed real vehicle nor first historical data exists in the simulated on-ramp, a traffic status in a free driving state is randomly selected from the first basic traffic graph, for assigning a value to the initial speed and a value to the vehicle outputting interval.
S1048: Set an initial vehicle speed and a vehicle outputting interval of the third virtual simulated vehicle according to the traffic status.
S1049: Remove a vehicle traveling to a downstream edge of a map.

In the digital twin driving simulation system, a vehicle in the first sensing region can be digitized and presented in the driving simulation system in real time. In this embodiment of the present disclosure, a traffic vehicle that may exist in a simulated ramp without sensed data is first initially set, to obtain a first virtual simulated vehicle. After the simulation starts to run, traveling of a vehicle on the simulated ramp is described, to maintain time-space continuity of the traffic status while making running of a simulated vehicle meets traffic running rules. Based on this, in this embodiments of the present disclosure, space-time deduction prediction can be performed on the traffic status of the simulated ramp after injection of sensed data is stooped, to achieve interactive fusion between a physical space and a digital space. Therefore, a decision basis can be better provided.

In view of the above, in this embodiment of the present disclosure, a simulated vehicle in a simulated ramp without sensed data is described neither at the simulation starting moment nor in the simulation reproduction stage. Therefore, accuracy of reproduction by the driving simulation system for a simulated ramp can be improved, thereby improving accuracy of reproduction of a simulated road. In addition, in this embodiment of the present disclosure, a simulated ramp in different simulation stages is described separately, so that accuracy of prediction by the driving simulation system for the simulated ramp can be improved, thereby improving accuracy of prediction of a simulated road.

Referring to FIG. 10, FIG. 10 is a schematic flowchart of a data processing method according to an embodiment of the present disclosure. The method may be performed by a service server (for example, the service server 100 shown in FIG. 1), or may be performed by a terminal device (for example, the terminal device 200a shown in FIG. 1), or may be performed by the service server and the terminal device interactively. For ease of understanding, this embodiment of the present disclosure is described by using an example in which the method is performed by a service server. As shown in FIG. 10, the method may include at least the following operations.

S201: Determine, in a driving simulation system, whether a simulated ramp connected to a simulated main road belongs to a sensing region with sensed data.

Specifically, for a specific implementation process of S201, reference may be made to S101 in the embodiment corresponding to FIG. 3, and details are not described herein again.

S202: Generate a first virtual simulated vehicle in the simulated ramp at a simulation starting moment in response to that the simulated ramp does not belong to the sensing region with the sensed data.

Specifically, an average vehicle spacing corresponding to the simulated ramp is determined according to a vehicle density in the first starting traffic status. If the simulated ramp is a simulated off-ramp, the first virtual simulated vehicle is generated in the simulated off-ramp according to the average vehicle spacing, a demerging point of the simulated off-ramp, and a traveling direction of the simulated off-ramp. In some embodiments, the demerging point is a meeting point between the simulated off-ramp and the main road.

For a scenario in which the simulated ramp is a simulated on-ramp, reference may be made to the foregoing descriptions of S102 in the embodiment corresponding to FIG. 3. This operation is for describing a simulated off-ramp. A process in which the service server determines a traffic status (which is the first starting traffic status or the second starting traffic status) of the simulated off-ramp at the simulation starting moment is the same as the process described in S102 for the simulated on-ramp. A difference between the simulated on-ramp and the simulated off-ramp is different generation directions of the first virtual simulated vehicle.

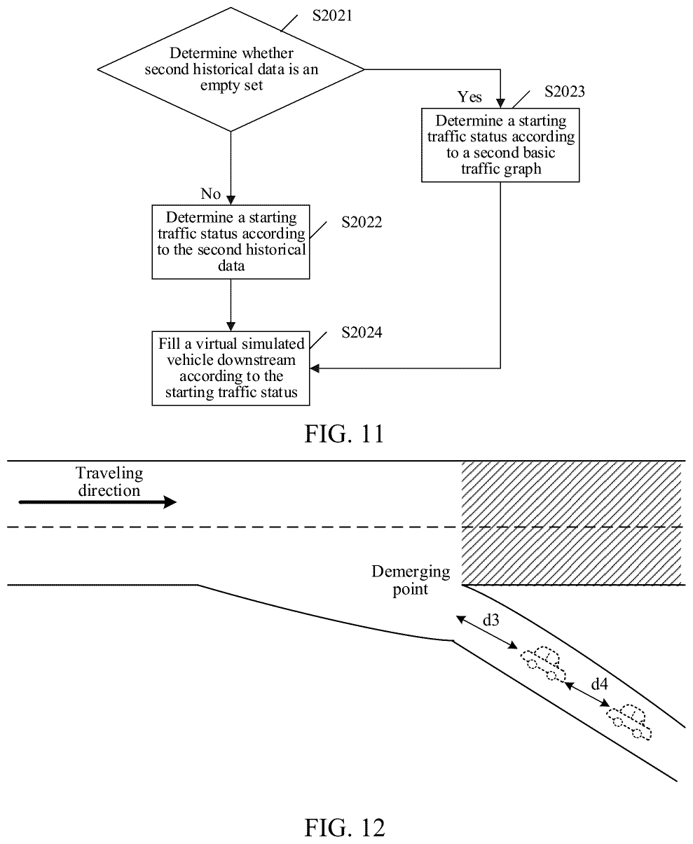

For a processing process of this operation, reference may also be made to FIG. 11. FIG. 11 is a schematic flowchart of a method for generating a virtual simulated vehicle for a simulated off-ramp at a simulation starting moment according to an embodiment of the present disclosure. As shown in FIG. 11, the method may include the following operations:

S2021: Determine whether second historical data is an empty set. In a scenario in which the second historical data is an empty set, the service server performs S2023. In a scenario in which the second historical data is not an empty set, the service server performs S2022. In this embodiment of the present disclosure, historical data corresponding to the simulated off-ramp is defined as second historical data.

S2022: The service server determines a starting traffic status, that is, the foregoing first starting traffic status, corresponding to the simulated off-ramp according to the second historical data. An implementation process of this operation is the same as the process in which the service server determines the first starting traffic status of the simulated on-ramp according to the first historical data in S102.

S2023: The service server determines a starting traffic status, that is, the foregoing second starting traffic status, corresponding to the simulated off-ramp according to the second basic traffic graph. In this embodiment of the present disclosure, a basic traffic graph corresponding to the simulated off-ramp is defined as a second basic traffic graph. An implementation process of this operation is the same as the process in which the service server determines the second starting traffic status of the simulated on-ramp according to the first basic traffic graph in S102.

S2024: Fill a virtual simulated vehicle downstream according to the starting traffic status (which is the first starting traffic status or the second starting traffic status). In a scenario in which the second historical data is not an empty set, the service server obtains historical data corresponding to the simulation starting moment from the second historical data as a first starting traffic status corresponding to the simulated off-ramp. The first starting traffic status includes a vehicle flow, a vehicle density, and a vehicle speed of the simulated off-ramp at the simulation starting moment. Further, according to the vehicle density in the first starting traffic status, the service server may determine an average vehicle spacing D6, that is, a distance between two virtual simulated vehicles corresponding to the simulated off-ramp. The service server generates a normal distribution N (D6, σ²) with the average vehicle spacing D6 as a mean. In this embodiment of the present disclosure, a specific distribution and a specific variance are not limited provided that diversity is ensured. Also referring to FIG. 12, FIG. 12 is a schematic diagram of a scenario of generating a first virtual simulated vehicle in a simulated off-ramp according to an embodiment of the present disclosure. As shown in FIG. 12, the service server searches for a distance di (a random value conforming to a normal distribution N (D6, σ²)) downstream of the simulated off-ramp starting from a demerging point of the simulated off-ramp as a location in the simulated off-ramp at which a virtual vehicle needs to be filled and generates vehicle spacings dj (j=i, i+1, . . . ) in sequence for filling virtual simulated vehicles downstream, for example, a vehicle spacing d3 to a vehicle spacing d4, as shown in FIG. 12. An order of filling is not limited in this embodiment of the present disclosure, and may be performed in order by lanes, that is, one lane is filled up first, and then another lane is filled, or a plurality of lanes close to a merging point may be filled first, and then backtracking is performed upstream. When a selected vehicle spacings dj exceeds a range of the simulated on-ramp (namely, an upstream edge of the simulated on-ramp) after being extended upstream, the service server determines that initialization on this lane of the simulated on-ramp is completed.

If the first historical data is an empty set, the service server randomly obtains, according to a basic traffic graph (second basic traffic graph for short) corresponding to the simulated off-ramp, a vehicle density in a free traveling state (equivalent to the target traffic status) in the second basic traffic graph. According to the vehicle density, the service server determines an average vehicle spacing D7 of the simulated off-ramp at the simulation starting moment. A subsequent process is the same as a process in which the service server fills the simulated off-ramp with a virtual simulated vehicle (namely, the first virtual simulated vehicle) according to the average vehicle spacing D6. Therefore, details are not described herein again, and reference may be made to the foregoing description.

Referring to FIG. 12 again, if the simulated off-ramp does not have sensed data, or the first sensing region does not include the simulated off-ramp in FIG. 12, a downstream main road of the simulated off-ramp, that is, a dashed region in FIG. 12, also does not have sensed data.

S203: Control, in a simulation reproduction stage after the simulation starting moment, if the simulated ramp is a simulated off-ramp, a driving behavior of at least one second virtual simulated vehicle traveling in the simulated off-ramp according to an autonomous driving model corresponding to the simulated off-ramp, to obtain a traffic status of the simulated off-ramp, the at least one second virtual simulated vehicle traveling in the simulated off-ramp including the first virtual simulated vehicle.

In some embodiments, the vehicle traveling in the simulated off-ramp further includes a sixth virtual simulated vehicle that is in a fifth virtual simulated vehicle traveling in the simulated main road and that travels from the simulated main road to the simulated off-ramp. An upstream region of the simulated off-ramp is a sensing blank region, and the upstream region belongs to the simulated main road. The sensing blank region is connected to a demerging point of the simulated off-ramp.

In some embodiments, the sixth virtual simulated vehicle that is in the fifth virtual simulated vehicle and that enters the simulated off-ramp is determined according to a distance between the fifth virtual simulated vehicle and the demerging point of the simulated off-ramp.

At the simulation starting moment, a filled initial vehicle, for example, the first virtual simulated vehicle in S202 described above, may exist in the simulated off-ramp. After the simulation starts to run, longitudinal and transverse driving behaviors of the first virtual simulated vehicle generated in the simulated off-ramp at the simulation starting moment are simulated through an autonomous driving model (including a following model and a lane changing model) corresponding to the simulated off-ramp. In this embodiment of the present disclosure, the autonomous driving model corresponding to the simulated off-ramp is defined as a second autonomous driving model.

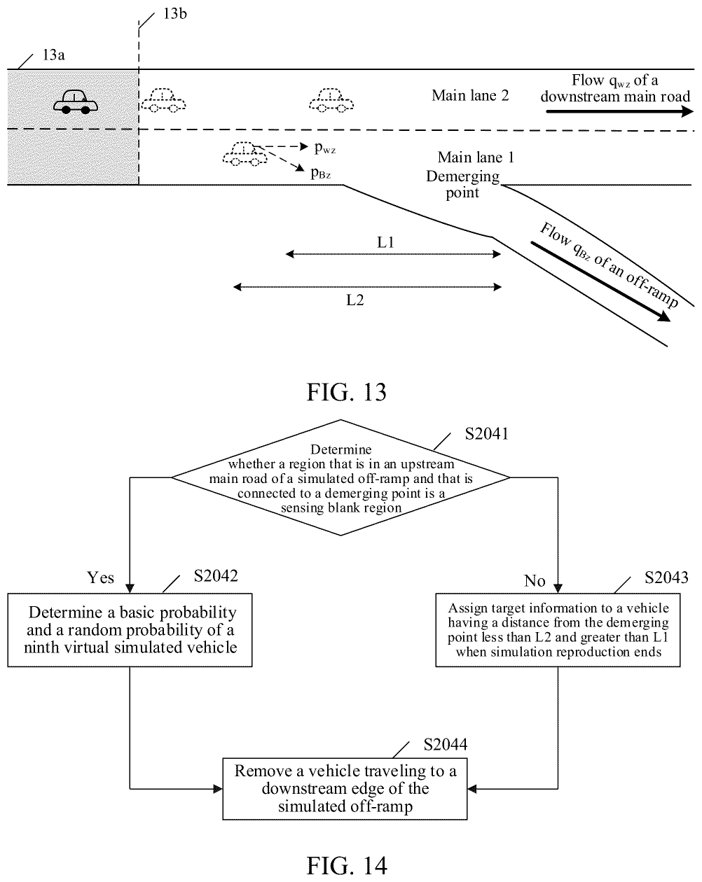

In this embodiment of the present disclosure, it is set that a sensing blank region exists in the upstream main road of the simulated off-ramp, and the sensing blank region is connected to the demerging point of the simulated off-ramp. In this scenario, a sensing coverage region may exist in an upstream region of the sensing blank region. Also referring to FIG. 13, FIG. 13 is a schematic diagram of a scenario of outputting a virtual simulated driving behavior in a simulated off-ramp according to an embodiment of the present disclosure. As shown in FIG. 13, a most upstream region of the simulated main road is a sensing coverage region 13a, and downstream regions of the simulated main road are all sensing blank regions. After a reproduced simulated vehicle generated in the sensing coverage region 13a crosses a lower sensing boundary 13b, since there is no sensed data supporting a driving simulation behavior of the reproduced simulated vehicle, the service server determines the reproduced simulated vehicle crossing the lower sensing boundary 13b as a seventh virtual simulated vehicle. Similar to the virtual simulated vehicle generated in the sensing blank region at the simulation starting moment, longitudinal and transverse driving behaviors of the seventh virtual simulated vehicle are simulated through an autonomous driving model (a following model and a lane changing model) corresponding to the sensing blank region.

If no sensing coverage region exists in the upstream main road of the simulated off-ramp, that is, all road segments of the upstream main road of the simulated off-ramp are sensing blank regions, in the simulation reproduction stage of the upstream main road of the simulated off-ramp, a second vehicle generation sub-region is generated, and then the service server generates a virtual simulated vehicle through the second vehicle generation sub-region. A processing process of the second vehicle generation sub-region is the same as the foregoing processing process of the first vehicle generation sub-region. The former is for a sensing blank region located furthest upstream, and the latter is located in the simulated on-ramp.

The seventh virtual simulated vehicle and a virtual simulated vehicle generated in the second vehicle generation sub-region are collectively referred to as a fifth virtual simulated vehicle below.

S2031: Determine, according to a distance between the fifth virtual simulated vehicle traveling in the simulated main road and the demerging point of the simulated off-ramp, the sixth virtual simulated vehicle that is in the fifth virtual simulated vehicle and that travels into the simulated off-ramp.

Referring to FIG. 13 again, L1 is a first preset distance, and is defined as a closest decision distance allowing a simulated vehicle to change a traveling target. L2 is a second preset distance, and is a demerging reaction distance for a vehicle to be aware of that a simulated off-ramp exists downstream.

According to the first preset distance L1 and the second preset distance L2, the fifth virtual simulated vehicle traveling in the simulated main road may be divided into three categories:
(1) having a distance from the demerging point greater than L2;
(2) having a distance from the demerging point greater than L1 and less than L2; and
(3) having a distance from the demerging point less than L1.

For a virtual simulated vehicle having a distance from the demerging point greater than L2, the virtual simulated vehicle is not aware of existence of the demerging point. For a virtual simulated vehicle having a distance from the demerging point greater than L1 and less than L2, the service server assigns target information (a simulated off-ramp or a downstream main road of the simulated off-ramp) to the vehicle. For a virtual simulated vehicle having a distance from the demerging point less than L2, there are two cases: one is that the virtual simulated vehicle is located in the road segment range corresponding to L1 at the simulation starting moment, and the other is that the virtual simulated vehicle travels into the road segment range corresponding to L1 only in the simulation reproduction stage.

For the fifth virtual simulated vehicle that is located in the road segment range corresponding to L1 at the simulation starting moment (that is, having a distance from the demerging point less than L1), the service server does not assign target information (a simulated off-ramp or a downstream main road of the simulated off-ramp) to the fifth virtual simulated vehicle, and the fifth virtual simulated vehicle continuously travels according to a current lane in which the fifth virtual simulated vehicle is located. For example, if a distance between a virtual simulated vehicle Rs and the demerging point is less than L1 at the simulation starting moment, the service server obtains current lane information of the virtual simulated vehicle Rs. If the current lane information is a main road lane 2 illustrated in FIG. 13, the distance between the virtual simulated vehicle Rs and the demerging point is less than the closest decision distance allowing a simulated vehicle to change a traveling target, and the current traveling lane is not connected to the simulated off-ramp. Therefore, the virtual simulated vehicle Rs travels to the downstream main road through the main road lane 2. If the current lane information is a main road lane 1 illustrated in FIG. 13, since the main road lane 1 is to fork, respectively leading to the simulated off-ramp and the simulated main road, the virtual simulated vehicle Rs may directly travels out of the main road and into the off-ramp without changing lanes and conflicting with main road traffic. Therefore, the service server may randomly select a direction for the virtual simulated vehicle Rs to travel.

For the virtual simulated vehicle that travels into the road segment range corresponding to L1 only in the simulation reproduction stage, when the virtual simulated vehicle travels into the road segment range corresponding to L2, the service server has assigned target information to the virtual simulated vehicle. Therefore, when entering the road segment range corresponding to L1, the virtual simulated vehicle may travel according to the previously assigned target information.

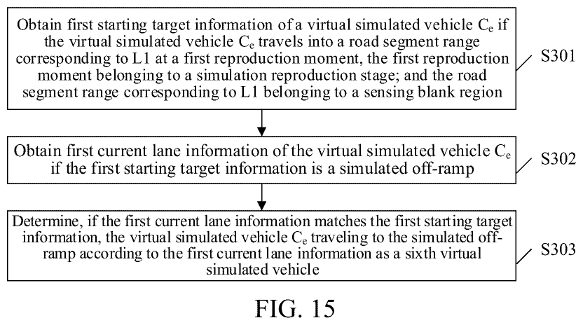

For a scenario in which a distance between the fifth virtual simulated vehicle and the demerging point at the simulation starting moment is greater than L1 and less than L2 (the foregoing category (2)), or a scenario in which a distance between the fifth virtual simulated vehicle and the demerging point at the simulation starting moment is greater than L2 (the foregoing category (1)), for example, a scenario in which the fifth virtual simulated vehicle travels into a sensing blank region only after the simulation reproduction stage starts to run, reference may be made to the following embodiment corresponding to FIG. 15. Details of this operation are not described.

S2032: Determine the sixth virtual simulated vehicle traveling into the simulated off-ramp determined in S2031 and the first virtual simulated vehicle as the second virtual simulated vehicle.

S2033: Output, according to the autonomous driving model corresponding to the simulated off-ramp, a virtual simulated driving behavior of the second virtual simulated vehicle in the simulated off-ramp; and remove, when the second virtual simulated vehicle travels to a downstream edge of the simulated off-ramp, the second virtual simulated vehicle from the driving simulation system, to obtain a traffic status of the simulated off-ramp.

The autonomous driving models described in this embodiment of the present disclosure each include a vehicle following algorithm and a vehicle lane changing algorithm. In the driving simulation system, a longitudinal driving behavior of a simulated vehicle is determined by a vehicle following algorithm. The algorithm includes a maximum traveling speed and a minimum safe vehicle spacing, respectively representing a maximum speed (for example, a road speed limit) that a vehicle cannot exceed during traveling and a minimum vehicle spacing that needs to be maintained during traveling. In each simulation step of the following algorithm, the present vehicle updates its own acceleration according to a location, a speed, and the like of a front vehicle.

A transverse driving behavior of a simulated vehicle is described by a rule-based lane changing algorithm. On the premise that the present vehicle has a willingness to change lanes, both a distance between the present vehicle and a front vehicle in a target lane and a distance between the present vehicle and a rear vehicle in the target lane are to be greater than a preset safety distance. A lane changing operation is performed only when safety conditions are met.

S204: Control, in a simulation prediction stage after the simulation reproduction stage, based on the traffic status of the simulated off-ramp obtained in the simulation reproduction stage, a driving behavior of a third virtual simulated vehicle traveling in the simulated off-ramp according to the autonomous driving model corresponding to the simulated off-ramp, to obtain a predicted traffic status of the simulated off-ramp, the predicted traffic status being configured to control a traveling state of a physical vehicle traveling on a physical road corresponding to the simulated off-ramp

Specifically, if the simulated ramp is a simulated off-ramp, a virtual simulated vehicle that enters a road segment range corresponding to L2 only in the simulation prediction stage and that is in an eighth virtual simulated vehicle traveling in a sensing blank region in an upstream main road of the simulated off-ramp is determined as a ninth virtual simulated vehicle. The sensing blank region does not belong to a sensing region with sensed data, and the sensing blank region is connected to a demerging point of the simulated off-ramp. A basic probability of the ninth virtual simulated vehicle for the simulated off-ramp is determined, and a random probability of the ninth virtual simulated vehicle for the simulated off-ramp is determined. Starting target information of the ninth virtual simulated vehicle is determined as the simulated off-ramp if the basic probability is greater than or equal to the random probability. The ninth virtual simulated vehicle is determined as a third virtual simulated vehicle if the ninth virtual simulated vehicle is driven according to the starting target information. A predicted simulated driving behavior of the third virtual simulated vehicle is outputted in the simulated off-ramp according to an autonomous driving model corresponding to the simulated off-ramp, a virtual simulated driving behavior, and a downstream edge of the simulated off-ramp. The downstream edge of the simulated off-ramp is configured for instructing the driving simulation system to remove, from the third virtual simulated vehicle, a virtual simulated vehicle driving to the downstream edge of the simulated off-ramp from the driving simulation system.

Also referring to FIG. 14, FIG. 14 is a schematic flowchart of a method for generating a predicted simulated driving behavior for a simulated off-ramp in a simulation prediction stage according to an embodiment of the present disclosure. The method may include the following operations:

S2041: Determine whether a region that is in an upstream main road of the simulated off-ramp and that is connected to the demerging point is a sensing blank region; perform S2042 if the region that is in the upstream main road of the simulated off-ramp and that is connected to the demerging point is a sensing blank region; and perform S2043 if the region that is in the upstream main road of the simulated off-ramp and that is connected to the demerging point is not a sensing blank region, that is, the region that is in the upstream main road of the simulated off-ramp and that is connected to the demerging point is a sensing region with sensed data.

S2042: Determine a basic probability and a random probability of a ninth virtual simulated vehicle. When the simulation reproduction stage ends, a virtual simulated vehicle located in the road segment range corresponding to L2 has generated the starting target information, or has been assigned a probability of traveling into the simulated off-ramp. Therefore, in the simulation prediction stage, such a simulated vehicle does not need to be processed, and only a virtual simulated vehicle that travels into the road segment range corresponding to L2 only in the simulation prediction stage needs to be considered.

S2043: Assign target information to a vehicle having a distance from the demerging point less than L2 and greater than L1 when simulation reproduction ends.

If a distance between a simulated vehicle and the demerging point at a moment when the simulation reproduction stage ends is less than L1, the processing herein is the same as the processing on the virtual simulated vehicle having a distance from the demerging point less than L1 at the simulation starting moment in S2031 stated above. If the simulated vehicle travels into the road segment range corresponding to L2 after the simulation prediction stage starts, processing of the simulated vehicle is the same as the following processing process in the embodiment corresponding to FIG. 15, in which the fifth virtual simulated vehicle travels into the road segment range corresponding to L2 only after the simulation reproduction stage starts to run.

S2044: Remove a virtual simulated vehicle traveling to a downstream edge of the simulated off-ramp.

In this solution, first, initial traffic statuses of an on-ramp and an off-ramp that are not covered by a sensing device are set respectively, and traffic running in different simulation stages is described respectively using a simulation timeline as a clue, thereby implementing space-time deduction prediction, and further implementing interactive fusion between a physical space and a digital space.

In view of the above, in this embodiment of the present disclosure, a simulated vehicle in a simulated ramp without sensed data is described neither at the simulation starting moment nor in the simulation reproduction stage. Therefore, accuracy of reproduction by the driving simulation system for a simulated ramp can be improved, thereby improving accuracy of reproduction of a simulated road. In addition, in this embodiment of the present disclosure, a simulated ramp in different simulation stages is described separately, so that accuracy of prediction by the driving simulation system for the simulated ramp can be improved, thereby improving accuracy of prediction of a simulated road.

Further, referring to FIG. 15, FIG. 15 is a schematic flowchart of a data processing method according to an embodiment of the present disclosure. As shown in FIG. 15, a process of the data processing method includes the following operations S301 to S303. In addition, S301 to S303 are a specific embodiment of S2031 in the embodiment corresponding to FIG. 10. The data processing process includes the following operations.

S301: Obtain first starting target information of a virtual simulated vehicle Cₑ if the virtual simulated vehicle Cₑ travels into a road segment range corresponding to L1 at a first reproduction moment, the first reproduction moment belonging to a simulation reproduction stage; and the road segment range corresponding to L1 belonging to a sensing blank region.

Specifically, the virtual simulated vehicle Cₑ belongs to the fifth virtual simulated vehicle, where e is a positive integer, and e is less than or equal to a total quantity of fifth virtual simulated vehicles. The first starting target information is determined when the virtual simulated vehicle Cₑ is located in a road segment range corresponding to L2, but has not entered the road segment range corresponding to L1 (a second reproduction moment).

In some embodiments, the determining of the first starting target information may be divided into the following two cases:

In the first case, the virtual simulated vehicle travels into the road segment range corresponding to L2 only in the simulation reproduction stage, that is, is located outside the road segment range corresponding to L2 at the simulation starting moment.

In this case, a process of determining the first starting target information may include: determining, if the virtual simulated vehicle Cₑ enters the road segment range corresponding to L2 at a second reproduction moment, a first basic probability of the virtual simulated vehicle Cₑ for the simulated off-ramp at the second reproduction moment, the second reproduction moment belonging to the simulation reproduction stage, and the second reproduction moment being earlier than the first reproduction moment; generating a first random probability for the virtual simulated vehicle Cₑ; and determining the first starting target information according to the first basic probability and the first random probability.

In some embodiments, an occasion for generating the first random probability may be further determined, including: determining a first target selection location corresponding to the virtual simulated vehicle Cₑ according to an aggressive parameter corresponding to the virtual simulated vehicle Cₑ, the first preset distance L1, and the second preset distance L2, the first target selection location having an inverse enhancement relationship (that is, a larger value of the aggressive parameter indicates a shorter distance between the first target selection location and the demerging point) with the aggressive parameter corresponding to the virtual simulated vehicle Cₑ; and generating the first random probability for the virtual simulated vehicle Cₑ when the virtual simulated vehicle Cₑ travels to the first target selection location.

A specific process of determining the first starting target information according to the first basic probability and the first random probability may include: determining the first starting target information as the simulated off-ramp if the first basic probability is greater than or equal to the first random probability; and determining the first starting target information as a downstream main road of the simulated off-ramp if the first basic probability is less than the first random probability, the downstream main road of the simulated off-ramp belonging to the simulated main road, the downstream main road of the simulated off-ramp being connected to the sensing blank region, and the downstream main road of the simulated off-ramp not belonging to the sensing region with the sensed data.

A specific process of determining a first basic probability of the virtual simulated vehicle Cₑ for the simulated off-ramp at the second reproduction moment may include: if historical data corresponding to the simulated off-ramp is not an empty set, and historical data corresponding to the downstream main road of the simulated off-ramp is not an empty set, obtaining an off-ramp vehicle flow corresponding to the second reproduction moment from the historical data corresponding to the simulated off-ramp, and obtaining a downstream main road vehicle flow corresponding to the second reproduction moment from the historical data corresponding to the downstream main road of the simulated off-ramp; determining a vehicle flow sum of the off-ramp vehicle flow and the downstream main road vehicle flow, and determining a ratio of the off-ramp vehicle flow to the vehicle flow sum as the first basic probability of the virtual simulated vehicle Cₑ for the simulated off-ramp at the second reproduction moment; and if the historical data corresponding to the simulated off-ramp is an empty set, and the historical data corresponding to the downstream main road of the simulated off-ramp is an empty set, obtaining a first lane count of the simulated off-ramp and a second lane count of the downstream main road of the simulated off-ramp, determining a lane count sum of the first lane count and the second lane count, and determining a ratio of the first lane count to the lane count sum as the first basic probability.

In the second case, at the simulation starting moment, the virtual simulated vehicle is located in the road segment range having a distance from the demerging point greater than L1 and less than L2, that is, is located in the road segment range corresponding to L2 (that has not entered the road segment range corresponding to L1) at the simulation starting moment.

Specifically, a process of determining the first starting target information may further include: determining a second basic probability of the virtual simulated vehicle Cₑ for the simulated off-ramp at a simulation starting moment if at the simulation starting moment, the virtual simulated vehicle Cₑ is located in the road segment range having a distance from the demerging point greater than L1 and less than L2; obtaining a second target selection location of the virtual simulated vehicle Cₑ at the simulation starting moment, and determining a selection probability of the virtual simulated vehicle Cₑ for the simulated off-ramp according to the second target selection location, an aggressive parameter corresponding to the virtual simulated vehicle Cₑ, the second basic probability, the first preset distance L1, and the second preset distance L2; generating a second random probability for the virtual simulated vehicle Cₑ, and determining the first starting target information as the simulated off-ramp if the selection probability is greater than or equal to the second random probability; and determining the first starting target information as a downstream main road of the simulated off-ramp if the selection probability is less than the second random probability, the downstream main road of the simulated off-ramp belonging to the simulated main road, the downstream main road of the simulated off-ramp being connected to the sensing blank region, and the downstream main road of the simulated off-ramp not belonging to the sensing region with the sensed data.

S2031 stated above describes a scenario in which a simulated vehicle is located in the road segment range corresponding to L1 at the simulation starting moment. This operation describes a scenario in which a virtual simulated vehicle travels into the road segment range corresponding to L1 after the simulation reproduction stage starts, for example, at the first reproduction moment as described above. The virtual simulated vehicle Cₑ may be in the following cases at the simulation starting moment: 1. The virtual simulated vehicle Cₑ is located in the road segment range corresponding to L2, and therefore, travels into the road segment range corresponding to L1 after the simulation reproduction stage is run. 2. The virtual simulated vehicle Cₑ is located upstream the road segment range corresponding to L2, or has not entered a sensing blank region, and therefore, after the simulation reproduction stage is run, first travels into the road segment range corresponding to L2, and then travels into the road segment range corresponding to L1.

Referring to the scenario of FIG. 13 again, if a distance between the virtual simulated vehicle Cₑ and the demerging point is greater than the second preset distance L2, that is, the virtual simulated vehicle Cₑ is located upstream the road segment range corresponding to L2, it is confirmed that no simulated off-ramp is found downstream. Therefore, the virtual simulated vehicle Cₑ is in a free lane changing state and does not generate target information, that is, the virtual simulated vehicle Cₑ may not change lanes toward an off-ramp or may maintain traveling on a main road. In this scenario, the virtual simulated vehicle Cₑ may include a vehicle that is located outside the road segment range corresponding to L2 at the simulation starting moment and a vehicle that has not entered the road segment range corresponding to L2 after the simulation starts to run.

If the virtual simulated vehicle Cₑ travels into the road segment range corresponding to L2 only after the simulation starts (that is, the second reproduction moment), to be specific, the virtual simulated vehicle Cₑ travels into the road segment range corresponding to L2 only after the simulation starts, but does not travel into the road segment range corresponding to L1, the simulated vehicle is aware of that an off-ramp exists downstream. The service server determines first starting target information for the virtual simulated vehicle Cₑ. It is determined according to a formula (3) that the first starting target information is the first basic probability of the simulated off-ramp if historical data corresponding to a downstream main road of the simulated off-ramp is not an empty set, and historical data corresponding to the simulated off-ramp is not an empty set.

$${p}_{B z} = {q}_{B z} / ( {q}_{B z} + {q}_{w z} ) \qquad ( 3 )$$

In the formula (3), p_{Bz} represents the first basic probability; q_{Bz} represents a flow of vehicles traveling out of the main road from the simulated off-ramp at the second reproduction moment in the historical data corresponding to the simulated off-ramp; and q_{wz} represents a flow of vehicles traveling on the downstream main road after passing the simulated off-ramp for the second reproduction moment in historical data corresponding to the downstream main road of the simulated off-ramp.

It is determined according to a formula (4) that the first starting target information is the first basic probability of the simulated off-ramp if historical data corresponding to a downstream main road of the simulated off-ramp is an empty set, and historical data corresponding to the simulated off-ramp is an empty set.

$${p}_{B z} = {N}_{B z} / ( {N}_{B z} + {N}_{w z} ) \qquad ( 4 )$$

In the formula (4), N_{Bz} is a lane count of the simulated off-ramp, and N_{wz} is a lane count of the main road after passing an exit of the simulated off-ramp. In the road structure shown in FIG. 13, N_{Bz}=1, and N_{wz}=2.

When generating the first starting target information, the service server calculates a random number p (namely, the foregoing first random probability) in a range of (0, 1) for the virtual simulated vehicle Cₑ, and when p<p_{Bi}, the vehicle chooses the off-ramp, and otherwise, chooses to continue traveling on the main road.

When a vehicle enters the road segment range corresponding to L2, to maintain diversity of traffic, locations (that is, the first target selection location) at which vehicles start to calculate their own random numbers p are distinguished. Assuming that the virtual simulated vehicle Cₑ starts to calculate the random value p only when having a distance Lₖ₁ from the demerging point, the first target selection location can be determined using the following formula (5):

$${L}_{k 1} = ( 1 - {A}_{k} ) \cdot {L}_{2} \qquad ( 5 )$$

In the formula (5), Lₖ₁ represents the first target selection location, Aₖ is an aggression degree of the vehicle, that is, the aggressive parameter, and has a value range of (0, 1). A larger value of Aₖ indicates the vehicle is more aggressive, and the vehicle calculates the random number p at a location closer to L1 (and the demerging point). A smaller value of Aₖ indicates that the vehicle is more conservative, and the vehicle calculates the random number p at a location farther away from L1 (and the demerging point).

After making a target decision (that is, the first starting target information) based on the random number p, the vehicle moves toward a lane indicated by the first starting target information. A movement manner is not limited herein, but it is to be ensured that the vehicle moves toward a lane at which the first starting target information can be implemented, for example, lane changing. For example, if the first starting target information is the simulated off-ramp, the simulated vehicle moves toward a lane connected to the simulated off-ramp.

If the virtual simulated vehicle Cₑ is located in the road segment range corresponding to L2 at the simulation starting moment, a location of the virtual simulated vehicle Cₑ at the simulation starting moment is determined as the second target selection location. A process of determining the second basic probability is the same as the process of determining the first basic probability. Therefore, details are not described herein again. The service server may determine a selection probability of the virtual simulated vehicle Cₑ for the simulated off-ramp according to the following formula (6):

$${p}_{k} = {p}_{B z} \cdot {A}_{k} \cdot ( {L}_{k 2} - L 1 ) / {L}_{2} \qquad ( 6 )$$

In the formula (6), pₖ represents the selection probability, P_{Bz} represents the second basic probability, and Lₖ₂ represents the second target selection location. In this case, that the vehicle is more aggressive (that is, the value of Aₖ is larger) indicates that the vehicle is farther away from the demerging point, and is more likely to select the off-ramp. An objective of the formula (6) is to select, at the simulation starting moment, first starting target information for a vehicle that is in the road segment range corresponding to L2 (that has not entered the road segment range corresponding to L1).

After the selection probability is calculated, a random number p (namely, the foregoing second random probability) in the range of (0, 1) is also taken, and when p<Pₖ, the vehicle chooses the off-ramp, and otherwise, chooses to continue traveling on the main road. After making a target decision based on the random number p, the vehicle moves toward the target lane. A movement manner is not limited herein, but it is to be ensured that the vehicle moves toward a lane at which the target can be achieved, for example, lane changing.

S302: Obtain first current lane information of the virtual simulated vehicle Cₑ if the first starting target information is the simulated off-ramp.

S303: Determine, if the first current lane information matches the first starting target information, the virtual simulated vehicle Cₑ traveling to the simulated off-ramp according to the first current lane information as the sixth virtual simulated vehicle.

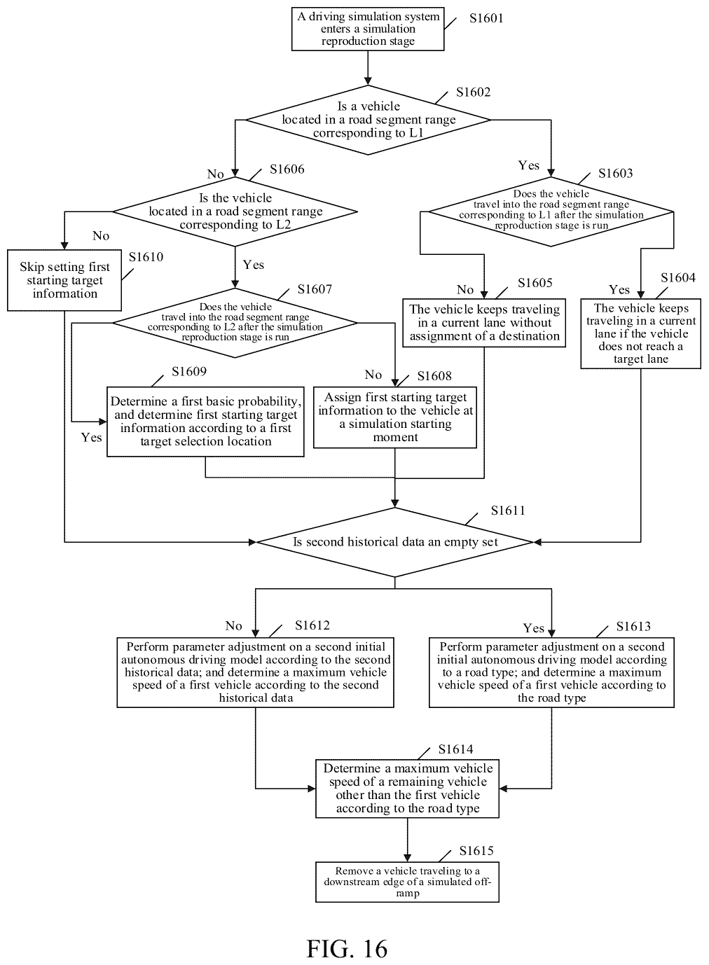

FIG. 16 may be generated by further combining FIG. 10 and this embodiment of the present disclosure. FIG. 16 is a schematic flowchart of a method for generating a virtual simulated driving behavior for a simulated off-ramp in a simulation reproduction stage according to an embodiment of the present disclosure. As shown in FIG. 16, the method may include the following operations.
S1601: The driving simulation system enters a simulation reproduction stage.
S1602: Determine whether a vehicle is located in a road segment range corresponding to L1; perform S1603 if the vehicle is located in the road segment range corresponding to L1; and perform S1606 if the vehicle is not located in the road segment range corresponding to L1.
S1603: Determine whether the vehicle travels into the road segment range corresponding to L1 after the simulation reproduction stage is run; perform S1604 if the vehicle travels into the road segment range corresponding to L1 after the simulation reproduction stage is run; and perform S1605 if the vehicle does not travel into the road segment range corresponding to L1 after the simulation reproduction stage is run.
S1604: The vehicle keeps traveling in a current lane if the vehicle does not reach a target lane.
S1605: The vehicle keeps traveling in a current lane without assignment of a destination.
S1606: Determine whether the vehicle is located in a road segment range corresponding to L2; perform S1607 if the vehicle is located in the road segment range corresponding to L2; and perform S1610 if the vehicle is not located in the road segment range corresponding to L2.
S1607: Determine whether the vehicle travels into the road segment range corresponding to L2 after the simulation reproduction stage is run; perform S1609 if the vehicle travels into the road segment range corresponding to L2 after the simulation reproduction stage is run; and perform S1608 if the vehicle does not travel into the road segment range corresponding to L2 after the simulation reproduction stage is run.
S1608. Assign first starting target information to the vehicle at the simulation starting moment.
S1609: Determine a first basic probability, and determine first starting target information according to a first target selection location.
S1610: Skip setting first starting target information.
S1611: Determine whether second historical data is an empty set; perform S1613 if the second historical data is an empty set; and perform S1612 if the second historical data is not an empty set.
S1612: Perform parameter adjustment on a second initial autonomous driving model according to the second historical data; determine a maximum vehicle speed of a first vehicle according to the second historical data; and determine the second initial autonomous driving model after the parameter adjustment as a second autonomous driving model.
S1613: Perform parameter adjustment on a second initial autonomous driving model according to a road type; and determine a maximum vehicle speed of a first vehicle according to the road type, the first vehicle in this embodiment of the present disclosure being a vehicle closest to a downstream edge in a simulated off-ramp.
S1614: Determine a maximum vehicle speed of a remaining vehicle other than the first vehicle according to the road type.
S1615: Remove a vehicle traveling to the downstream edge of the simulated off-ramp.

Embodiments involved in the present disclosure, for example, the embodiments corresponding to FIG. 3, FIG. 10, and FIG. 15, may all be combined into a new embodiment.

In view of the above, in this embodiment of the present disclosure, a simulated vehicle in a simulated ramp without sensed data is described neither at the simulation starting moment nor in the simulation reproduction stage. Therefore, accuracy of reproduction by the driving simulation system for a simulated ramp can be improved, thereby improving accuracy of reproduction of a simulated road. In addition, in this embodiment of the present disclosure, a simulated ramp in different simulation stages is described separately, so that accuracy of prediction by the driving simulation system for the simulated ramp can be improved, thereby improving accuracy of prediction of a simulated road.

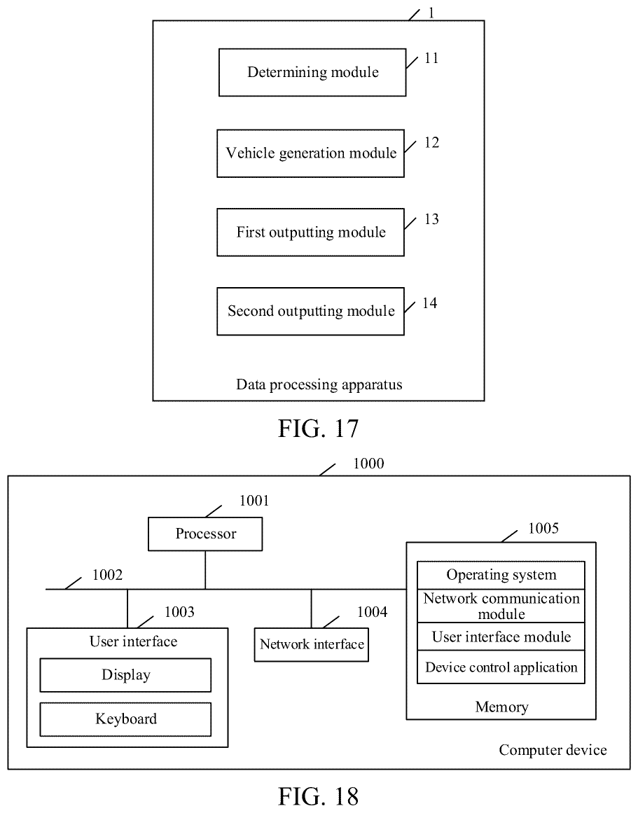

Further, referring to FIG. 17, FIG. 17 is a schematic structural diagram of a data processing apparatus according to an embodiment of the present disclosure. A data processing apparatus 1 may be configured to perform the corresponding operations in the method shown provided in the embodiments of the present disclosure. As shown in FIG. 17, the data processing apparatus 1 may include a determining module 11, a vehicle generation module 12, a first outputting module 13, and a second outputting module 14.

The determining module 11 is configured to determine, in a driving simulation system, whether a simulated ramp connected to a simulated main road belongs to a sensing region with sensed data.

The vehicle generation module 12 is configured to generate a first virtual simulated vehicle in the simulated ramp at a simulation starting moment in response to that the simulated ramp does not belong to the sensing region with the sensed data.

The first outputting module 13 is configured to control, in a simulation reproduction stage after the simulation starting moment, a driving behavior of at least one second virtual simulated vehicle traveling in the simulated ramp according to an autonomous driving model corresponding to the simulated ramp, to obtain a traffic status of the simulated ramp, the second virtual simulated vehicle traveling in the simulated ramp including the first virtual simulated vehicle.

The second outputting module 14 is configured to control, in a simulation prediction stage after the simulation reproduction stage, based on the traffic status of the simulated ramp obtained in the simulation reproduction stage, a driving behavior of a third virtual simulated vehicle traveling in the simulated ramp according to the autonomous driving model corresponding to the simulated ramp, to obtain a predicted traffic status of the simulated ramp, the predicted traffic status being configured to control a traveling state of a physical vehicle traveling on a physical road corresponding to the simulated ramp.

For specific functional implementations of the determining module 11, the vehicle generation module 12, the first outputting module 13, and the second outputting module 14, reference may be made to S101 to S104 in the embodiment corresponding to FIG. 3. Details are not described herein again.

In view of the above, in this embodiment of the present disclosure, a simulated vehicle in a simulated ramp without sensed data is described neither at the simulation starting moment nor in the simulation reproduction stage. Therefore, accuracy of reproduction by the driving simulation system for a simulated ramp can be improved, thereby improving accuracy of reproduction of a simulated road. In addition, in this embodiment of the present disclosure, a simulated ramp in different simulation stages is described separately, so that accuracy of prediction by the driving simulation system for the simulated ramp can be improved, thereby improving accuracy of prediction of a simulated road.

Further, referring to FIG. 18, FIG. 18 is a schematic structural diagram of a computer device according to an embodiment of the present disclosure. As shown in FIG. 18, the computer device 1000 may include at least one processor 1001 such as a CPU, at least one network interface 1004, a user interface 1003, a memory 1005, and at least one communication bus 1002. The communication bus 1002 is configured to implement connection and communication between the components. In some embodiments, the user interface 1003 may include a display and a keyboard. In some embodiments, the network interface 1004 may include a standard wired interface and a standard wireless interface (such as a Wi-Fi interface). The memory 1005 may be a high-speed random access memory (RAM), or may be a non-volatile memory, for example, at least one magnetic disk memory. In some embodiments, the memory 1005 may be at least one storage apparatus located remotely from the foregoing processor 1001. As shown in FIG. 18, the memory 1005 used as a computer-readable storage medium may include an operating system, a network communication module, a user interface module, and a device control application.

In the computer device 1000 shown in FIG. 18, the network interface 1004 may provide a network communication function. The user interface 1003 is mainly configured to provide an input interface for a user. The processor 1001 may be configured to invoke the device control application stored in the memory 1005, to implement the following operations:
determining, in the driving simulation system, whether a simulated ramp connected to a simulated main road belongs to a sensing region with sensed data;
generating a first virtual simulated vehicle in the simulated ramp at a simulation starting moment in response to that the simulated ramp does not belong to the sensing region with the sensed data;
controlling, in a simulation reproduction stage after the simulation starting moment, a driving behavior of at least one second virtual simulated vehicle traveling in the simulated ramp according to an autonomous driving model corresponding to the simulated ramp, to obtain a traffic status of the simulated ramp, the second virtual simulated vehicle traveling in the simulated ramp including the first virtual simulated vehicle; and
controlling, in a simulation prediction stage after the simulation reproduction stage, based on the traffic status of the simulated ramp obtained in the simulation reproduction stage, a driving behavior of a third virtual simulated vehicle traveling in the simulated ramp according to the autonomous driving model corresponding to the simulated ramp, to obtain a predicted traffic status of the simulated ramp, the predicted traffic status being configured to control a traveling state of a physical vehicle traveling on a physical road corresponding to the simulated ramp.

The computer device 1000 described in this embodiment of the present disclosure can implement the descriptions of the data processing method or apparatus in the foregoing embodiments. Details are not described herein again. In addition, for the descriptions about beneficial effects of adopting the same method, details are not described herein again.

An embodiment of the present disclosure further provides a computer-readable storage medium. The computer-readable storage medium has a computer program stored therein. The computer program, when executed by a processor, implements the descriptions of the data processing method or apparatus in the foregoing embodiments. Details are not described herein again. In addition, for the descriptions about beneficial effects of adopting the same method, details are not described herein again.

The computer-readable storage medium may be a data processing apparatus or an internal storage unit of the foregoing computer device, for example, a hard drive or a memory of the computer device, provided in any one of the foregoing embodiments. The computer-readable storage medium may alternatively be an external storage device of the computer device, for example, a removable hard drive, a smart memory card (SMC), a secure digital (SD) card, or a flash card equipped on the computer device. Further, the computer-readable storage medium may also include both an internal storage unit and an external storage device of the computer device. The computer-readable storage medium is configured to store the computer program and another program and data that are required by the computer device. The computer-readable storage medium may also be configured to temporarily store data that has been outputted or to-be-outputted data.

The embodiments of the present disclosure further provide a computer program product, including a computer program. The computer program is stored in a computer-readable storage medium. A processor of a computer device reads the computer program from the computer-readable storage medium. The processor executes the computer program, to cause the computer device to perform the descriptions about the data processing method or apparatus in the foregoing embodiments. Details are not described herein again. In addition, for the descriptions about beneficial effects of adopting the same method, details are not described herein again.

In the specification, claims, and accompanying drawings of the present disclosure, the terms “first” and “second” are intended to distinguish between different objects but do not indicate a particular order. In addition, terms, such as “include”, and any variations thereof are intended to indicate non-exclusive inclusion. For example, a process, method, apparatus, product, or device that includes a series of operations or units is not limited to the listed operations or units; and instead, in some embodiments, further includes an operation or unit that is not listed, or in some embodiments, further includes another operation or unit that is intrinsic to the process, method, apparatus, product, or device.

A person of ordinary skill in the art may be aware that, with reference to the exemplary units and algorithm operations described in the embodiments disclosed in this specification, the present disclosure may be implemented by electronic hardware, computer software, or a combination thereof. To clearly describe interchangeability between the hardware and the software, the exemplary compositions and operations have been generally described according to functions in the foregoing descriptions. Whether the functions are performed by hardware or software depends on particular applications and design constraint conditions of the technical solutions. A person skilled in the art may use different methods to implement the described functions for each particular application, but such implementation is not to be considered as exceeding the scope of the present disclosure.

Disclosed above are merely exemplary embodiments of the present disclosure, and are certainly not intended to limit the patent scope of the present disclosure. Therefore, an equivalent change made according to the claims of the present disclosure still falls within the scope of the present disclosure.

What is claimed is:

1. A data processing method, performed by a computer device running a driving simulation system, the method comprising:
determining, in the driving simulation system, whether a simulated ramp connected to a simulated main road belongs to a sensing region with sensed data;
generating a first virtual simulated vehicle in the simulated ramp at a simulation starting moment in response to that the simulated ramp does not belong to the sensing region with the sensed data;
controlling, in a simulation reproduction stage after the simulation starting moment, a driving behavior of at least one second virtual simulated vehicle traveling in the simulated ramp according to an autonomous driving model corresponding to the simulated ramp, to obtain a traffic status of the simulated ramp, the at least one second virtual simulated vehicle traveling in the simulated ramp comprising the first virtual simulated vehicle; and
controlling, in a simulation prediction stage after the simulation reproduction stage, based on the traffic status of the simulated ramp obtained in the simulation reproduction stage, a driving behavior of a third virtual simulated vehicle traveling in the simulated ramp according to the autonomous driving model corresponding to the simulated ramp, to obtain a predicted traffic status of the simulated ramp, the predicted traffic status being configured to control a traveling state of a physical vehicle traveling on a physical road corresponding to the simulated ramp.

2. The method according to claim 1, wherein the generating a first virtual simulated vehicle in the simulated ramp comprises:
obtaining, in response to that historical data corresponding to the simulated ramp is not an empty set, historical data corresponding to the simulation starting moment from the historical data corresponding to the simulated ramp as a first starting traffic status corresponding to the simulated ramp, and generating the first virtual simulated vehicle in the simulated ramp according to the first starting traffic status; and
determining a second starting traffic status corresponding to the simulated ramp according to a target traffic status in a basic traffic graph corresponding to the simulated ramp in response to that the historical data corresponding to the simulated ramp is an empty set, and generating the first virtual simulated vehicle in the simulated ramp according to the second starting traffic status.

3. The method according to claim 2, wherein the generating the first virtual simulated vehicle in the simulated ramp according to the first starting traffic status comprises:
determining an average vehicle spacing corresponding to the simulated ramp according to a vehicle density in the first starting traffic status;
generating, in response to that the simulated ramp is a simulated on-ramp, the first virtual simulated vehicle in the simulated on-ramp, according to the average vehicle spacing, starting from a merging point of the simulated on-ramp in a direction opposite to a traveling direction of the simulated on-ramp; and
generating, in response to that the simulated ramp is a simulated off-ramp, the first virtual simulated vehicle in the simulated off-ramp, according to the average vehicle spacing, starting from a demerging point of the simulated off-ramp in a traveling direction of the simulated off-ramp.

4. The method according to claim 1, wherein the simulated ramp includes a simulated on-ramp, the method further comprises:
determining a vehicle outputting region in the simulated on-ramp; and
generating a fourth virtual simulated vehicle in the vehicle outputting region; and
the at least one second virtual simulated vehicle traveling in the simulated ramp in the simulation reproduction stage further comprises the fourth virtual simulated vehicle.

5. The method according to claim 4, further comprising:
generating, in response to that a sensing coverage region exists in a downstream region of the simulated on-ramp, a first vehicle removal line perpendicular to a traveling direction of the simulated on-ramp at an upstream edge of the sensing coverage region, the downstream region of the simulated on-ramp belonging to the simulated main road, and the sensing coverage region belonging to the sensing region with the sensed data; and
removing, from the driving simulation system, a virtual simulated vehicle that is one of the at least one second virtual simulated vehicle and that travels to the first vehicle removal line.

6. The method according to claim 4, further comprising:
determining, as a first vehicle in the simulated on-ramp, a virtual simulated vehicle that is one of the at least one second virtual simulated vehicle and that is closest to a downstream edge of the simulated on-ramp; and
determining a maximum vehicle speed of the first vehicle according to historical data corresponding to the simulated on-ramp; and
determining a vehicle other than the first vehicle in the at least one second virtual simulated vehicle as an upstream vehicle in the simulated on-ramp;
determining a maximum vehicle speed of the upstream vehicle according to a road type corresponding to the simulated on-ramp; and
controlling the driving behavior of the at least one second virtual simulated vehicle traveling in the simulated on-ramp according to an autonomous driving model corresponding to the simulated on-ramp, comprising:
controlling the driving behavior of the at least one second virtual simulated vehicle traveling in the simulated on-ramp according to the autonomous driving model corresponding to the simulated on-ramp, the maximum vehicle speed of the upstream vehicle, and the maximum vehicle speed of the first vehicle.

7. The method according to claim 1, wherein the simulated ramp includes a simulated off-ramp, the at least one second virtual simulated vehicle traveling in the simulated off-ramp further comprises: a sixth virtual simulated vehicle that is in a fifth virtual simulated vehicle traveling in the simulated main road and that travels from the simulated main road to the simulated off-ramp; an upstream region of the simulated off-ramp is a sensing blank region, and the upstream region belongs to the simulated main road, the sensing blank region being connected to a demerging point of the simulated off-ramp; and
the method further comprises removing, from the driving simulation system, a virtual simulated vehicle that is one of the at least one second virtual simulated vehicle and that travels to a downstream edge of the simulated off-ramp.

8. The method according to claim 7, further comprising: determining, according to a distance between the fifth virtual simulated vehicle and the demerging point of the simulated off-ramp, the sixth virtual simulated vehicle that is in the fifth virtual simulated vehicle and that enters the simulated off-ramp.

9. The method according to claim 8, wherein first starting target information of the fifth virtual simulated vehicle is obtained in response to that the fifth virtual simulated vehicle enters a road segment range at a distance from the demerging point less than a first preset distance in the simulation reproduction stage; and
first current lane information of the fifth virtual simulated vehicle is obtained in response to that the first starting target information is the simulated off-ramp; and
in response to that the first current lane information matches the first starting target information, the fifth virtual simulated vehicle traveling to the simulated off-ramp according to the first current lane information is determined as the sixth virtual simulated vehicle.

10. The method according to claim 8, further comprising:
determining first starting target information of the fifth virtual simulated vehicle when the fifth virtual simulated vehicle enters a road segment range at a distance from the demerging point greater than a first preset distance and less than a second preset distance,
the determining first starting target information comprising:
determining a first basic probability of the fifth virtual simulated vehicle for the simulated off-ramp; and
generating a first random probability for the fifth virtual simulated vehicle; and
determining the first starting target information according to the first basic probability and the first random probability.

11. The method according to claim 10, wherein the generating a first random probability for the fifth virtual simulated vehicle comprises:
determining a first target selection location corresponding to the fifth virtual simulated vehicle according to an aggressive parameter corresponding to the fifth virtual simulated vehicle, the first preset distance, and the second preset distance, a larger aggressive parameter indicating that the first target selection location is closer to the demerging point; and
generating the first random probability for the fifth virtual simulated vehicle when the fifth virtual simulated vehicle travels to the first target selection location.

12. The method according to claim 10, wherein the determining the first starting target information according to the first basic probability and the first random probability comprises:
determining the first starting target information as the simulated off-ramp in response to that the first basic probability is greater than or equal to the first random probability; and
determining the first starting target information as a downstream main road of the simulated off-ramp in response to that the first basic probability is less than the first random probability, the downstream main road of the simulated off-ramp belonging to the simulated main road, the downstream main road of the simulated off-ramp being connected to the sensing blank region, and the downstream main road of the simulated off-ramp not belonging to the sensing region with the sensed data.

13. The method according to claim 10, wherein the determining a first basic probability of the fifth virtual simulated vehicle for the simulated off-ramp comprises:
in response to that historical data corresponding to the simulated off-ramp is not an empty set, and historical data corresponding to the downstream main road of the simulated off-ramp is not an empty set, obtaining a corresponding off-ramp vehicle flow from the historical data corresponding to the simulated off-ramp, and obtaining a corresponding downstream main road vehicle flow from the historical data corresponding to the downstream main road of the simulated off-ramp;
determining a vehicle flow sum of the off-ramp vehicle flow and the downstream main road vehicle flow, and determining a ratio of the off-ramp vehicle flow to the vehicle flow sum as the first basic probability of the fifth virtual simulated vehicle for the simulated off-ramp; and
in response to that the historical data corresponding to the simulated off-ramp is an empty set, and the historical data corresponding to the downstream main road of the simulated off-ramp is an empty set, obtaining a first lane count of the simulated off-ramp and a second lane count of the downstream main road of the simulated off-ramp, determining a lane count sum of the first lane count and the second lane count, and determining a ratio of the first lane count to the lane count sum as the first basic probability.

14. A computer device, comprising: a processor, a memory, and a network interface,
the processor being connected to the memory and the network interface, the network interface being configured to provide a data communication function, the memory being configured to store a computer program, the processor being configured to invoke the computer program, to cause the computer device to perform:
determining, in a driving simulation system run by the computer device, whether a simulated ramp connected to a simulated main road belongs to a sensing region with sensed data;
generating a first virtual simulated vehicle in the simulated ramp at a simulation starting moment in response to that the simulated ramp does not belong to the sensing region with the sensed data;
controlling, in a simulation reproduction stage after the simulation starting moment, a driving behavior of at least one second virtual simulated vehicle traveling in the simulated ramp according to an autonomous driving model corresponding to the simulated ramp, to obtain a traffic status of the simulated ramp, the at least one second virtual simulated vehicle traveling in the simulated ramp comprising the first virtual simulated vehicle; and
controlling, in a simulation prediction stage after the simulation reproduction stage, based on the traffic status of the simulated ramp obtained in the simulation reproduction stage, a driving behavior of a third virtual simulated vehicle traveling in the simulated ramp according to the autonomous driving model corresponding to the simulated ramp, to obtain a predicted traffic status of the simulated ramp, the predicted traffic status being configured to control a traveling state of a physical vehicle traveling on a physical road corresponding to the simulated ramp.

15. The computer device according to claim 14, wherein the generating a first virtual simulated vehicle in the simulated ramp comprises:
obtaining, in response to that historical data corresponding to the simulated ramp is not an empty set, historical data corresponding to the simulation starting moment from the historical data corresponding to the simulated ramp as a first starting traffic status corresponding to the simulated ramp, and generating the first virtual simulated vehicle in the simulated ramp according to the first starting traffic status; and
determining a second starting traffic status corresponding to the simulated ramp according to a target traffic status in a basic traffic graph corresponding to the simulated ramp in response to that the historical data corresponding to the simulated ramp is an empty set, and generating the first virtual simulated vehicle in the simulated ramp according to the second starting traffic status.

16. The computer device according to claim 15, wherein the generating the first virtual simulated vehicle in the simulated ramp according to the first starting traffic status comprises:
determining an average vehicle spacing corresponding to the simulated ramp according to a vehicle density in the first starting traffic status;
generating, in response to that the simulated ramp is a simulated on-ramp, the first virtual simulated vehicle in the simulated on-ramp, according to the average vehicle spacing, starting from a merging point of the simulated on-ramp in a direction opposite to a traveling direction of the simulated on-ramp; and
generating, in response to that the simulated ramp is a simulated off-ramp, the first virtual simulated vehicle in the simulated off-ramp, according to the average vehicle spacing, starting from a demerging point of the simulated off-ramp in a traveling direction of the simulated off-ramp.

17. The computer device according to claim 14, wherein the simulated ramp includes a simulated on-ramp, the method further comprises:
determining a vehicle outputting region in the simulated on-ramp; and
generating a fourth virtual simulated vehicle in the vehicle outputting region; and
the at least one second virtual simulated vehicle traveling in the simulated ramp in the simulation reproduction stage further comprises the fourth virtual simulated vehicle.

18. The computer device according to claim 17, wherein the processor is further configured to perform:
generating, in response to that a sensing coverage region exists in a downstream region of the simulated on-ramp, a first vehicle removal line perpendicular to a traveling direction of the simulated on-ramp at an upstream edge of the sensing coverage region, the downstream region of the simulated on-ramp belonging to the simulated main road, and the sensing coverage region belonging to the sensing region with the sensed data; and
removing, from the driving simulation system, a virtual simulated vehicle that is one of the at least one second virtual simulated vehicle and that travels to the first vehicle removal line.

19. The computer device according to claim 17, wherein the processor is further configured to perform:
determining, as a first vehicle in the simulated on-ramp, a virtual simulated vehicle that is one of the at least one second virtual simulated vehicle and that is closest to a downstream edge of the simulated on-ramp; and
determining a maximum vehicle speed of the first vehicle according to historical data corresponding to the simulated on-ramp; and
determining a vehicle other than the first vehicle in the at least one second virtual simulated vehicle as an upstream vehicle in the simulated on-ramp;
determining a maximum vehicle speed of the upstream vehicle according to a road type corresponding to the simulated on-ramp; and
controlling the driving behavior of the at least one second virtual simulated vehicle traveling in the simulated on-ramp according to an autonomous driving model corresponding to the simulated on-ramp, comprising:
controlling the driving behavior of the at least one second virtual simulated vehicle traveling in the simulated on-ramp according to the autonomous driving model corresponding to the simulated on-ramp, the maximum vehicle speed of the upstream vehicle, and the maximum vehicle speed of the first vehicle.

20. A non-transitory computer-readable storage medium, having a computer program stored therein, the computer program being adapted to be loaded and executed by a processor, to cause a computer device comprising the processor to perform:
determining, in a driving simulation system run by the computer device, whether a simulated ramp connected to a simulated main road belongs to a sensing region with sensed data;
generating a first virtual simulated vehicle in the simulated ramp at a simulation starting moment in response to that the simulated ramp does not belong to the sensing region with the sensed data;
controlling, in a simulation reproduction stage after the simulation starting moment, a driving behavior of at least one second virtual simulated vehicle traveling in the simulated ramp according to an autonomous driving model corresponding to the simulated ramp, to obtain a traffic status of the simulated ramp, the at least one second virtual simulated vehicle traveling in the simulated ramp comprising the first virtual simulated vehicle; and
controlling, in a simulation prediction stage after the simulation reproduction stage, based on the traffic status of the simulated ramp obtained in the simulation reproduction stage, a driving behavior of a third virtual simulated vehicle traveling in the simulated ramp according to the autonomous driving model corresponding to the simulated ramp, to obtain a predicted traffic status of the simulated ramp, the predicted traffic status being configured to control a traveling state of a physical vehicle traveling on a physical road corresponding to the simulated ramp.
